(19) United States
(12) Patent Application Publication
(10) Pub. No.: US 2026/0271763 A1
(43) Pub. Date: Sep. 10, 2026

(54) METHOD FOR FORMING COPPER PILLARS BY COPPER PASTE SCREEN PRINTING

(71) Applicant: SKYWORKS SOLUTIONS, INC., Irvine, CA (US)

(72) Inventors: Kezia Cheng, Lowell, MA (US); Boris Dzyubenko, Billerica, MA (US); Michael J. Duval, Topsfield, MA (US)

(21) Appl. No.: 19/554,059

(22) Filed: Mar. 2, 2026

Related U.S. Application Data
(60) Provisional application No. 63/768,431, filed on Mar. 7, 2025.
(60) Provisional application No. 63/942,943, filed on Dec. 17, 2025.

(51) Int. Cl. H10W 72/00; H10W 72/20

(52) U.S. Cl. CPC H10W 72/01204; H10W 72/01223; H10W 72/01257; H10W 72/01265; H10W 72/252

(57) ABSTRACT

Aspects and embodiments disclosed herein include a method of forming copper pillars on a semiconductor substrate. The method comprises depositing a layer of a first photoresist on the substrate, exposing the first photoresist, depositing a layer of a second photoresist on the layer of the first photoresist, forming an aperture in the layer of the second photoresist by exposing and developing a portion of the layer of the second photoresist, forming a cavity in the layer of the first photoresist below the aperture in the layer of the second photoresist, depositing copper paste within the cavity, and sintering the copper paste.

### CROSS-REFERENCE TO RELATED APPLICATIONS

This application claims priority under 35 U.S.C. § 119(e) to U.S. Provisional Patent Application Ser. No. 63/942,943, titled “METHOD FOR FORMING COPPER PILLARS BY COPPER PASTE SCREEN PRINTING,” filed Dec. 17, 2025, and to U.S. Provisional Patent Application Ser. No. 63/768,431, titled “METHOD FOR FORMING COPPER PILLARS BY THICK FILM SCREEN PRINTING,” filed Mar. 7, 2025, the entire content of each being incorporated herein by reference for all purposes.

### BACKGROUND

### Technical Field

Embodiments disclosed herein relate to methods of forming electronic device contacts including copper pillars.

### Description of Related Technology

The compound semiconductor industry has been transitioning from wire bonding to flip chip die attach in recent years. Compared to through wafer via (TWV) and wire bonding, flip chip technology offers many performance and process advantages, such as better heat dissipation and lower electrical resistance.

A copper pillar formation process typically starts with a planarization process using a polymer. The pillar locations are either developed or etched open. A plating seed layer is sputtered on the wafer followed by a pattern plating lithography process. Typical commercial copper plating systems can achieve a plating rate of 0.3 μm/min. Because the copper pillar height is typically in the tens of microns range, with typical copper pillar heights being between 30 and 50 μm, the plating step takes a long time and is a bottleneck in the copper pillar formation process flow. After plating, the photoresist is stripped. A seed layer removal step that follows completes the copper pillar process.

The copper pillar bump formation process flow involves many steps and can take five to six days to complete. It is still the mainstream industry standard process for GaAs and GaN wafer fabrication foundries.

Other than the very long cycle time, coplanarity is an issue with the plated pillar approach. Large area bar bumps will plate up faster than smaller pillars. The wafers will typically go through a 3D automated optical inspection (AOI) process to reject dies that do not meet pillar height coplanarity specifications.

### SUMMARY

In accordance with one aspect, there is provided a method of forming copper pillars on a semiconductor substrate. The method comprises disposing a screen printing stencil above the semiconductor substrate, screen printing a copper paste through apertures in the screen printing stencil and onto the semiconductor substrate, and sintering the copper paste to form discrete copper pillars.

In some embodiments, screen printing the copper paste through the apertures in the screen printing stencil and onto the semiconductor substrate includes pushing the copper paste through the apertures in the screen printing stencil with a squeegee.

In some embodiments, the method is performed without utilizing photoresist or photolithography to define dimensions of the discrete copper pillars.

In some embodiments, the method further comprises disposing a second screen printing stencil above the semiconductor substrate, aligning apertures in the second screen printing stencil with the discrete copper pillars, and screen printing solder paste through the apertures in the second screen printing stencil and onto the discreet copper pillars.

In some embodiments, screen printing the solder paste through the apertures in the second screen printing stencil and onto the discrete copper pillars includes pushing the solder paste through the apertures in the second screen printing stencil with a squeegee.

In some embodiments, the method further comprises reflowing the solder paste on the discrete copper pillars.

In some embodiments, the copper paste is screen printed directly onto the semiconductor substrate.

In some embodiments, the copper paste is screen printed onto a layer of copper previously formed on the semiconductor substrate.

In some embodiments, the method further comprises forming a heat spreader of the semiconductor substrate by depositing an initial contiguous layer of copper paste on a surface of the semiconductor substrate, the initial contiguous layer of copper paste defining a base of the heat spreader, and sintering the initial contiguous layer of copper paste to form a sintered base of the heat spreader including the layer of copper previously formed on the semiconductor substrate, wherein screen printing the copper paste through the apertures in the screen printing stencil and onto the semiconductor substrate includes screen printing the copper paste through the apertures in the screen printing stencil and onto the sintered base of the heat spreader, the discrete copper pillars defining sintered fins of the heat spreader.

In some embodiments, the method further comprises increasing heights of the sintered fins of the heat spreader by disposing a second screen printing stencil above the sintered fins of the heat spreader, apertures of the second screen printing stencil being aligned above the sintered fins of the heat spreader, screen printing additional copper paste through the apertures in the second screen printing stencil and onto the sintered fins of the heat spreader, and sintering the additional copper paste.

In accordance with another aspect, there is provided a method of forming copper pillars on a semiconductor substrate. The method comprises depositing a layer of photoresist on an upper surface of the semiconductor substrate, defining a cavity in the layer of photoresist, depositing copper paste within the cavity, sintering the copper paste to form a solidified copper pillar within the cavity, removing an upper portion of the layer of photoresist, depositing solder on an upper end of the solidified copper pillar while leaving a lower portion of the layer of photoresist in place about a lower portion of the solidified copper pillar, and reflowing the solder.

In some embodiments, the cavity in the layer of photoresist exposes a portion of the upper surface of the semiconductor substrate.

In some embodiments, the cavity in the layer of photoresist is defined by photolithographically exposing and developing a portion of the photoresist.

In some embodiments, the copper paste is deposited into the cavity by vacuum-assisted screen printing.

In some embodiments, removing the upper portion of the layer of photoresist is performed by plasma etching.

In some embodiments, removing the upper portion of the layer of photoresist removes contaminants from the upper end of the solidified copper pillar.

In some embodiments, depositing the solder includes screen printing solder paste on the upper end of the solidified copper pillar.

In some embodiments, depositing the solder includes blanket depositing solder paste on the solidified copper pillar and lower portion of the layer of photoresist.

In some embodiments, the solder is deposited on the upper end of the solidified copper pillar by wave soldering.

In accordance with another aspect, there is provided a method of mounting a semiconductor die to a multichip module substrate. The method comprises depositing a layer of photoresist on an upper surface of the semiconductor die, defining a cavity in the layer of photoresist, depositing copper paste within the cavity, sintering the copper paste to form a solidified copper pillar within the cavity, placing a stencil over an upper surface of the multichip module substrate, depositing solder paste through the stencil onto the upper surface of the multichip module substrate, reflowing the deposited solder paste to form a solder contact, flip chip mounting the semiconductor die onto the multichip module substrate, the solidified copper pillar being aligned with the solder contact, and bonding the solidified copper pillar to the solder contact.

In accordance with another aspect, there is provided a method of forming a copper pillar bump on a substrate. The method comprises depositing a layer of a first photoresist on the substrate, exposing the first photoresist, depositing a layer of a second photoresist on the layer of the first photoresist, forming an aperture in the layer of the second photoresist by exposing and developing a portion of the layer of the second photoresist, forming a cavity in the layer of the first photoresist below the aperture in the layer of the second photoresist, depositing copper paste within the cavity, and sintering the copper paste.

In some embodiments, the copper paste is deposited by screen printing.

In some embodiments, the copper paste is deposited by vacuum assisted screen printing.

In some embodiments, the method further comprises exposing the layer of the first photoresist prior to depositing the layer of the second photoresist.

In some embodiments, forming the cavity in the layer of the first photoresist includes developing a portion of the layer of the first photoresist below the aperture in the layer of the second photoresist.

In some embodiments, the layer of the first photoresist and the layer of the second photoresist are not removed prior to sintering the copper paste.

In some embodiments, the aperture in the layer of the second photoresist is laterally offset from the cavity in the layer of the first photoresist.

In some embodiments, the method further comprises depositing solder paste on top of the copper paste after sintering the copper paste, and reflowing the solder paste.

In some embodiments, the solder paste is deposited within the cavity.

In some embodiments, the method further comprises removing the layer of the first photoresist and the layer of the second photoresist prior to reflowing the solder paste.

In some embodiments, the solder paste is deposited by screen printing.

In some embodiments, the solder paste is deposited by vacuum assisted screen printing.

In some embodiments, the solder paste is deposited at least partially within the aperture in the layer of the second photoresist.

In some embodiments, the method further comprises removing an upper portion of the layer of the second photoresist prior to reflowing the solder paste with a lower portion of the layer of the second photoresist remaining while reflowing the solder paste.

In some embodiments, the method further comprises forming a second copper pillar bump on the substrate.

In some embodiments, the aperture in the layer of the second photoresist defines a trench extending from the copper pillar bump to the second copper pillar bump.

In some embodiments, the method further comprises depositing the copper paste within the trench.

In some embodiments, the trench includes at least one spiral shaped portion.

In some embodiments, the aperture in the layer of the second photoresist defines a trench extending from the copper pillar bump.

In some embodiments, the method further comprises forming a redistribution layer in the trench.

In accordance with another aspect, there is provided a method of forming a copper pillar bump on a substrate. The method comprises depositing a layer of a photoresist on the substrate, depositing a release layer on an upper surface of the layer of the photoresist, depositing a layer of epoxy on an upper surface of the release layer, defining a cavity in the layer of epoxy, the release layer, and the layer of photoresist, depositing copper paste within the cavity, sintering the copper paste to form a sintered copper pillar, peeling away the layer of epoxy and release layer from about the sintered copper pillar, applying solder paste atop the sintered copper pillar, and reflowing the solder paste.

In some embodiments, the release layer is polyvinyl alcohol.

### BRIEF DESCRIPTION OF THE DRAWINGS

Embodiments of this disclosure will now be described, by way of non-limiting example, with reference to the accompanying drawings.

FIG. 1A illustrates an act in a first example of a process of forming a copper pillar bump on a wafer;

FIG. 1B illustrates another act in the first example of a process of forming a copper pillar bump on a wafer;

FIG. 1C illustrates another act in the first example of a process of forming a copper pillar bump on a wafer;

FIG. 1D illustrates another act in the first example of a process of forming a copper pillar bump on a wafer;

FIG. 1E illustrates another act in the first example of a process of forming a copper pillar bump on a wafer;

FIG. 1F illustrates another act in the first example of a process of forming a copper pillar bump on a wafer;

FIG. 1G illustrates another act in the first example of a process of forming a copper pillar bump on a wafer;

FIG. 1H illustrates another act in the first example of a process of forming a copper pillar bump on a wafer;

FIG. 1I illustrates another act in the first example of a process of forming a copper pillar bump on a wafer;

FIG. 2A illustrates an act in a second example of a process of forming a copper pillar bump on a wafer;

FIG. 2B illustrates another act in the second example of a process of forming a copper pillar bump on a wafer;

FIG. 2C illustrates another act in the second example of a process of forming a copper pillar bump on a wafer;

FIG. 2D illustrates another act in the second example of a process of forming a copper pillar bump on a wafer;

FIG. 2E illustrates another act in the second example of a process of forming a copper pillar bump on a wafer;

FIG. 2F illustrates another act in the second example of a process of forming a copper pillar bump on a wafer;

FIG. 2G illustrates another act in the second example of a process of forming a copper pillar bump on a wafer;

FIG. 2H illustrates another act in the second example of a process of forming a copper pillar bump on a wafer;

FIG. 3A illustrates an act in a third example of a process of forming a copper pillar bump on a wafer;

FIG. 3B illustrates another act in the third example of a process of forming a copper pillar bump on a wafer;

FIG. 3C illustrates another act in the third example of a process of forming a copper pillar bump on a wafer;

FIG. 3D illustrates another act in the third example of a process of forming a copper pillar bump on a wafer;

FIG. 3E illustrates another act in the third example of a process of forming a copper pillar bump on a wafer;

FIG. 3F illustrates another act in the third example of a process of forming a copper pillar bump on a wafer;

FIG. 3G illustrates another act in the third example of a process of forming a copper pillar bump on a wafer;

FIG. 3H illustrates an alternative to the act illustrated in FIG. 3F in the third example of a process of forming a copper pillar bump on a wafer;

FIG. 3I illustrates another alternative to the act illustrated in FIG. 3F in the third example of a process of forming a copper pillar bump on a wafer;

FIG. 3D1 illustrates an act in a modification to the process shown in FIGS. 3A-3I;

FIG. 3E1 illustrates another act in a modification to the process shown in FIGS. 3A-3I;

FIG. 3F1 illustrates another act in a modification to the process shown in FIGS. 3A-3I;

FIG. 3G1 illustrates another act in a modification to the process shown in FIGS. 3A-3I;

FIG. 3H1 illustrates another act in a modification to the process shown in FIGS. 3A-3I;

FIG. 3I1 illustrates another act in a modification to the process shown in FIGS. 3A-3I;

FIG. 4A illustrates an act in a fourth example of a process of forming a copper pillar bump on a wafer;

FIG. 4B illustrates another act in the fourth example of a process of forming a copper pillar bump on a wafer;

FIG. 4C illustrates another act in the fourth example of a process of forming a copper pillar bump on a wafer;

FIG. 4D illustrates another act in the fourth example of a process of forming a copper pillar bump on a wafer;

FIG. 4E illustrates another act in the fourth example of a process of forming a copper pillar bump on a wafer;

FIG. 4F illustrates another act in the fourth example of a process of forming a copper pillar bump on a wafer;

FIG. 4G illustrates another act in the fourth example of a process of forming a copper pillar bump on a wafer;

FIG. 4H illustrates another act in the fourth example of a process of forming a copper pillar bump on a wafer;

FIG. 4I illustrates another act in the fourth example of a process of forming a copper pillar bump on a wafer;

FIG. 4E1 illustrates an act in a variation of the fourth example of a process of forming a copper pillar bump on a wafer;

FIG. 4F1 illustrates another act in a variation of the fourth example of a process of forming a copper pillar bump on a wafer;

FIG. 4G1 illustrates another act in a variation of the fourth example of a process of forming a copper pillar bump on a wafer;

FIG. 4H1 illustrates another act in a variation of the fourth example of a process of forming a copper pillar bump on a wafer;

FIG. 4I1 illustrates another act in a variation of the fourth example of a process of forming a copper pillar bump on a wafer;

FIG. 4D2 illustrates an act in a variation of the fourth example of a process of forming a copper pillar bump on a wafer;

FIG. 4E2 illustrates another act in a variation of the fourth example of a process of forming a copper pillar bump on a wafer;

FIG. 4F2 illustrates another act in a variation of the fourth example of a process of forming a copper pillar bump on a wafer;

FIG. 4G2 illustrates another act in a variation of the fourth example of a process of forming a copper pillar bump on a wafer;

FIG. 4H2 illustrates another act in a variation of the fourth example of a process of forming a copper pillar bump on a wafer;

FIG. 5A illustrates an act in an example of a process of forming an inductor on a wafer;

FIG. 5B illustrates another act in the example of a process of forming an inductor on a wafer;

FIG. 5C illustrates another act in the example of a process of forming an inductor on a wafer;

FIG. 5D illustrates another act in the example of a process of forming an inductor on a wafer;

FIG. 5E illustrates another act in the example of a process of forming an inductor on a wafer;

FIG. 5F illustrates another act in the example of a process of forming an inductor on a wafer;

FIG. 5G illustrates another act in the example of a process of forming an inductor on a wafer;

FIG. 5H illustrates another act in the example of a process of forming an inductor on a wafer;

FIG. 5I illustrates an act in an example of a process of concurrently forming a circuit element and copper pillar bumps on a wafer;

FIG. 5J illustrates another act in the example of the process of concurrently forming the circuit element and copper pillar bumps on a wafer;

FIG. 5K illustrates another act in the example of the process of concurrently forming the circuit element and copper pillar bumps on a wafer;

FIG. 5L illustrates another act in the example of the process of concurrently forming the circuit element and copper pillar bumps on a wafer;

FIG. 5M illustrates another act in the example of the process of concurrently forming the circuit element and copper pillar bumps on a wafer;

FIG. 5N illustrates another act in the example of the process of concurrently forming the circuit element and copper pillar bumps on a wafer;

FIG. 5O illustrates another act in the example of the process of concurrently forming the circuit element and copper pillar bumps on a wafer;

FIG. 5P illustrates another act in the example of the process of concurrently forming the circuit element and copper pillar bumps on a wafer;

FIG. 5Q illustrates another act in the example of the process of concurrently forming the circuit element and copper pillar bumps on a wafer;

FIG. 5R illustrates another act in the example of the process of concurrently forming the circuit element and copper pillar bumps on a wafer;

FIG. 5S illustrates another act in the example of the process of concurrently forming the circuit element and copper pillar bumps on a wafer;

FIG. 5T illustrates another act in the example of the process of concurrently forming the circuit element and copper pillar bumps on a wafer;

FIG. 5I1 illustrates an act in another example of a process of concurrently forming a circuit element and copper pillar bumps on a wafer;

FIG. 5J1 illustrates another act in other example of the process of concurrently forming a circuit element and copper pillar bumps on a wafer;

FIG. 5K1 illustrates another act in other example of the process of concurrently forming a circuit element and copper pillar bumps on a wafer;

FIG. 5L1 illustrates another act in other example of the process of concurrently forming a circuit element and copper pillar bumps on a wafer;

FIG. 5M1 illustrates another act in other example of the process of concurrently forming a circuit element and copper pillar bumps on a wafer;

FIG. 5N1 illustrates another act in other example of the process of concurrently forming a circuit element and copper pillar bumps on a wafer;

FIG. 5O1 illustrates another act in other example of the process of concurrently forming a circuit element and copper pillar bumps on a wafer;

FIG. 5P1 illustrates another act in other example of the process of concurrently forming a circuit element and copper pillar bumps on a wafer;

FIG. 5Q1 illustrates another act in other example of the process of concurrently forming a circuit element and copper pillar bumps on a wafer;

FIG. 5R1 illustrates another act in other example of the process of concurrently forming a circuit element and copper pillar bumps on a wafer;

FIG. 5S1 illustrates another act in other example of the process of concurrently forming a circuit element and copper pillar bumps on a wafer;

FIG. 5T1 illustrates another act in other example of the process of concurrently forming a circuit element and copper pillar bumps on a wafer;

FIG. 5U1 illustrates another act in other example of the process of concurrently forming a circuit element and copper pillar bumps on a wafer;

FIG. 6A illustrates an example of a heat spreader formed from copper paste disposed on a semiconductor die;

FIG. 6B illustrates an act in an example of a process of forming a heat spreader on a semiconductor die from copper paste;

FIG. 6C illustrates another act in the example of the process of forming the heat spreader on the semiconductor die from copper paste;

FIG. 6D illustrates an act in an example of an alternative process of forming a heat spreader on a semiconductor die from copper paste;

FIG. 6E illustrates another act in the example of the alternative process of forming the heat spreader on the semiconductor die from copper paste;

FIG. 6F illustrates another act in the example of the alternative process of forming the heat spreader on the semiconductor die from copper paste;

FIG. 6G illustrates another act in the example of the alternative process of forming the heat spreader on the semiconductor die from copper paste;

FIG. 7A illustrates an act in an example of a process of forming a pick and place heat spreader from copper paste;

FIG. 7B illustrates another act in the example of the process of forming the pick and place heat spreader from copper paste;

FIG. 7C illustrates another act in the example of the process of forming the pick and place heat spreader from copper paste;

FIG. 7D illustrates another act in the example of the process of forming the pick and place heat spreader from copper paste;

FIG. 7E illustrates another act in the example of the process of forming the pick and place heat spreader from copper paste;

FIG. 8A illustrates an act in a fifth example of a process of forming a copper pillar bump on a wafer;

FIG. 8B illustrates another act in the fifth example of a process of forming a copper pillar bump on a wafer;

FIG. 8C illustrates another act in the fifth example of a process of forming a copper pillar bump on a wafer;

FIG. 8D illustrates another act in the fifth example of a process of forming a copper pillar bump on a wafer;

FIG. 8E illustrates another act in the fifth example of a process of forming a copper pillar bump on a wafer;

FIG. 9A illustrates an act in a process of forming electric contacts and/or traces on a multichip module;

FIG. 9B illustrates another act in a process of forming electric contacts and/or traces on a multichip module;

FIG. 9C illustrates another act in a process of forming electric contacts and/or traces on a multichip module;

FIG. 9D illustrates flip-chip bonding a die to the electric contacts and/or traces on the multichip module;

FIG. 10A illustrates an act in a process of forming a multi-chip module including an electromagnetic signal shield between devices;

FIG. 10B illustrates another act in the process of forming the multi-chip module including the electromagnetic signal shield between the devices;

FIG. 10C illustrates another act in the process of forming the multi-chip module including the electromagnetic signal shield between the devices;

FIG. 10D illustrates another act in the process of forming the multi-chip module including the electromagnetic signal shield between the devices;

FIG. 10E illustrates another act in the process of forming the multi-chip module including the electromagnetic signal shield between the devices; and

FIG. 10F illustrates another act in the process of forming the multi-chip module including the electromagnetic signal shield between the devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments disclosed herein may improve upon issues common to current copper pillar bump (CPB) processes including coplanarity issues, long cycle times, and die cracking due to mismatch in coefficient of thermal expansion between copper and material of the die.

Aspects and embodiments disclosed herein employ screen printing to apply thick film copper paste to form copper pillars on a wafer. In the context of this application, the term “screen printing” may refer to techniques including using a squeegee to spread copper paste into desired locations under vacuum, optionally without the use of a stencil or screen, printing solder paste or copper paste through apertures in a stencil, for example, with a squeegee, and/or to depositing solder paste or copper paste through a mesh screen into a desired location. Traditional copper thick film processes require high temperature firing to drive out the binder/carrier solvent and to solidify the copper particles. In recent years, however, low sinter temperature copper paste has become available from companies such as Resonac Holdings Corporation and Hitachi Chemical Co. LTD. Reasonable resistivity of 5 mOhm-cm or lower can be achieved after sintering at a temperature between 120° C. and 300° C. or between 140° C. and 200°. The low sintering temperature and the nanoparticle size make these pastes favorable for compound semiconductor applications.

In a screen or stencil printing process (the two processes referred to collectively herein as “screen printing” unless otherwise indicated) in which material is screen printed directly onto a planar surface, the primary thickness control is the screen mesh count and mesh thickness in processes utilizing a screen or the stencil thickness in processes utilizing a stencil. Regardless of the geometry and features of copper pillars formed with the same screen printing screen or stencil, the pillar height of the screen-printed pillars will be the same. This mitigates the coplanarity issue common with processes involving forming copper pillars by electroplating.

In other processes disclosed herein, copper paste may be deposited within openings defined within a dry film or photoresist. The deposited copper paste may be flush with the upper surface of dry film of photoresist, again, mitigating the coplanarity issue common with processes involving forming copper pillars by electroplating.

A screen printing process has very high throughput and does not require expensive sputter tools and plating systems. The process is much shorter with high throughput compared to prior industry standard copper pillar formation processes utilizing electroplating. Aspects and embodiments disclosed herein may thus mitigate the long cycle time issue common to many prior CPB fabrication processes.

In accordance with some aspects and embodiments disclosed herein two layers of dry film photoresist are applied to the surface of a semiconductor wafer from which the pillar locations are developed away. The wafer is then placed on a screen-printer where the copper paste is pushed into the pillar resist openings with a squeegee. Because no stencil is used in this screen-printing process, no stencil alignment is needed. The wafer is then sintered to cure the copper paste into a solid pillar. The sintering temperature may be between 120° C. and 300° C. or between 180° C. and 200° C. In some embodiments, polyimide dry film photoresist is chosen for its high glass transition temperature (Tg), which can be as high as 300° C. Either a single or multiple, for example, two, layers of dry film photoresist may be used to achieve the desired final thickness of the pillar (30 to 50 μm). In processes utilizing two layers of photoresist, the two layers of photoresist can be exposed with two separate masks making small pitch changes possible as well as making it possible to add redistribution layers, inductors, baluns, and/or other circuit elements the same time as formation of the CPBs.

In accordance with other aspects and embodiments disclosed herein the copper paste may be directly screen-printed onto the wafer. A screen or stencil mask may be utilized. Mask alignment may be used to place the pillars at the correct locations on the wafer. In this process, the copper pillar height is determined by the screen mesh or stencil thickness.

There are several differences between the aspects and embodiments disclosed herein and previous solutions. In prior industry standard copper pillar plating processes, the pillar height is controlled by the plating time, plating bath temperature, applied current, duty cycle, etc. Large area pillars such as bar bumps will plate up faster than smaller pillars. The difference in pillar height is problematic in flip chip die attach. Dies that do not meet the coplanarity specification will be rejected in automated optical inspection (AOI). In some processes utilizing plating to form copper pillars, 5 to 10% of the dies are rejected due to coplanarity issue.

Direct screen printing does not require expensive sputter tools or plating systems. Furthermore, pattern plating lithography and seed removal steps are not needed. The simplicity of the process translates into high throughput and lower wafer cost. In a screen printing process, the copper pillar height is controlled by the screen mesh size or stencil thickness. This is regardless of the size and geometry of the pillar. So higher yield is achieved than in prior art processes.

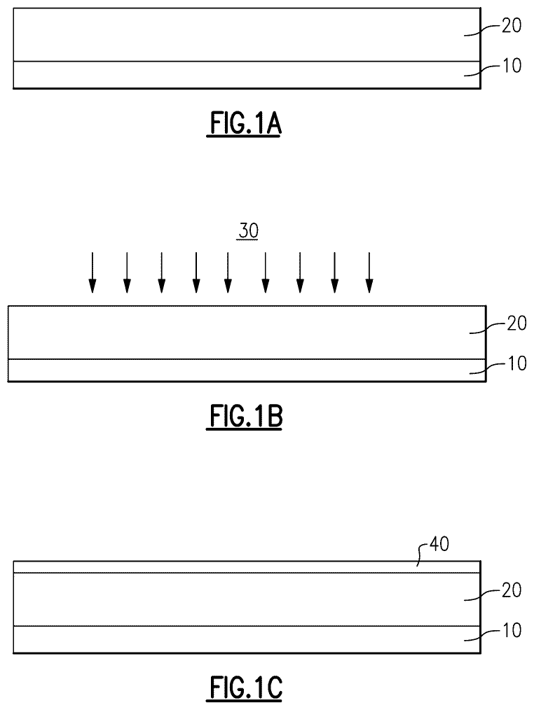

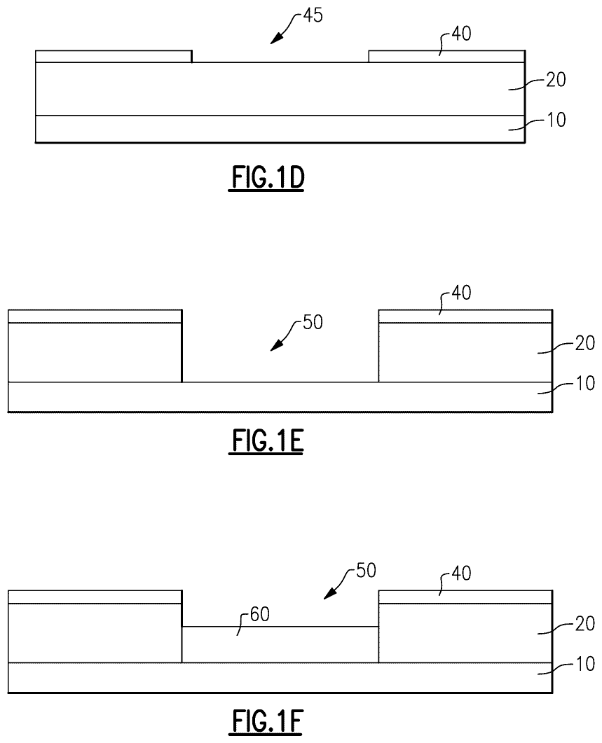

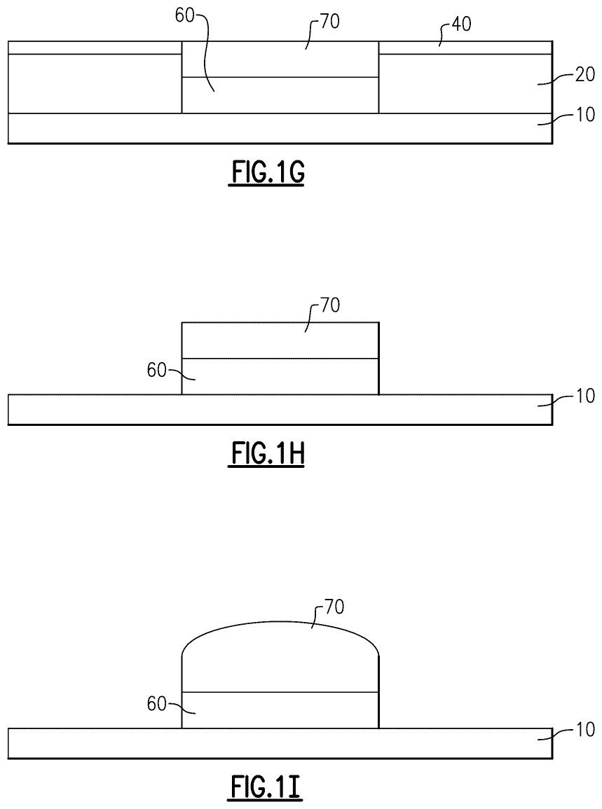

Acts included in one embodiment of a CPB process in accordance with the present disclosure are illustrated in FIGS. 1A-1I. In an act illustrated in FIG. 1A a semiconductor wafer 10, for example a GaAs, GaN, Si, InP, or other semiconductor wafer is provided and a layer of a first photoresist 20 is deposited on the upper surface of the wafer 10. The first photoresist 20 may be polyimide or PMGI and may be deposited by a spin on process as is known in the art.

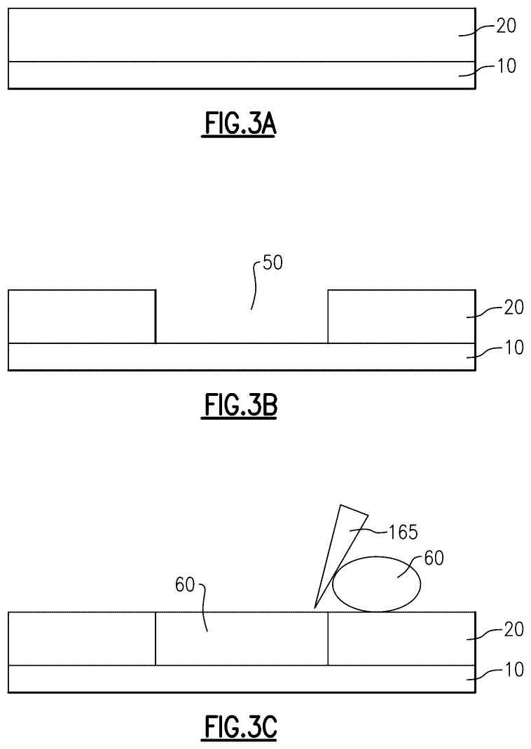

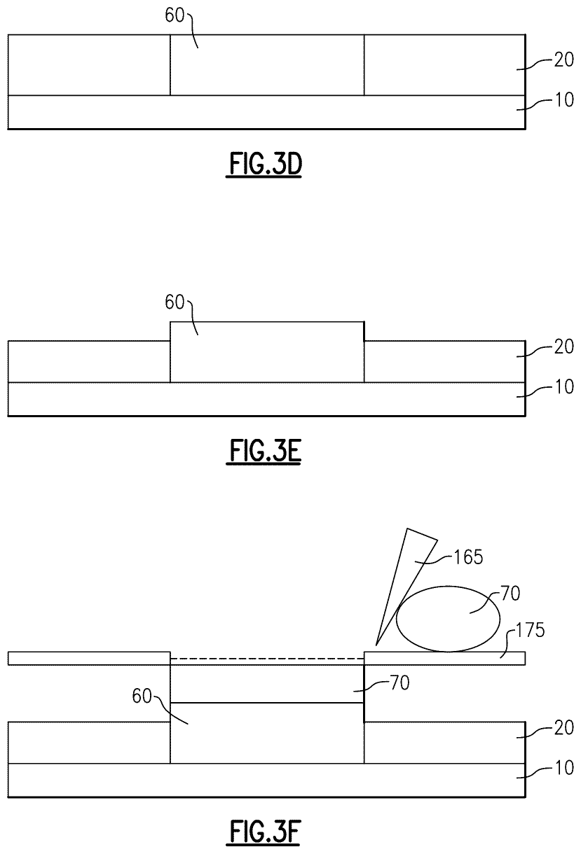

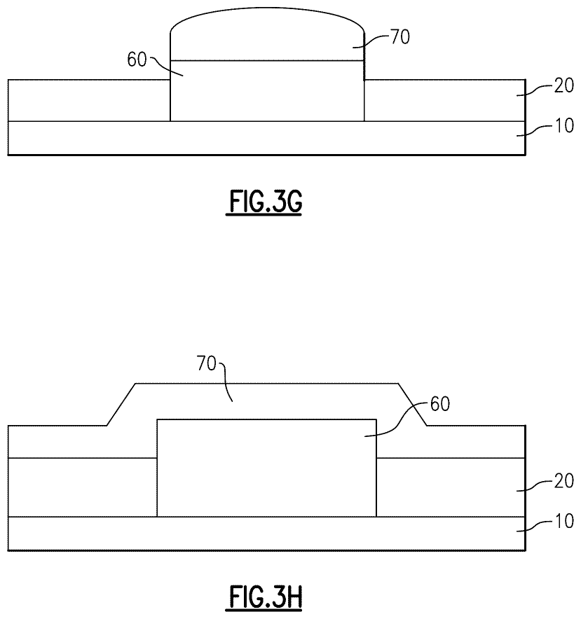

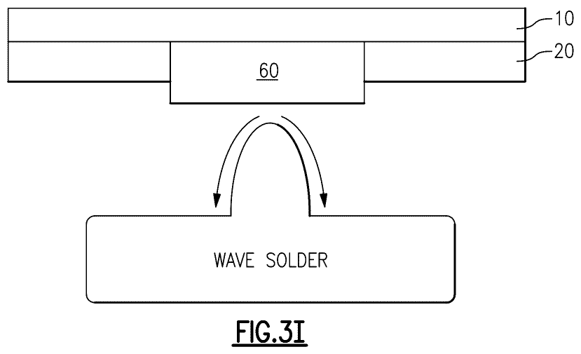

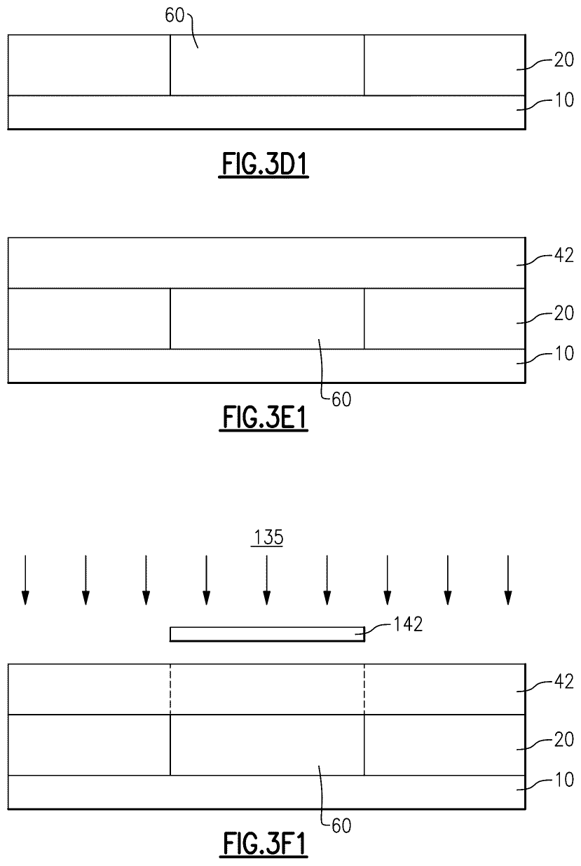

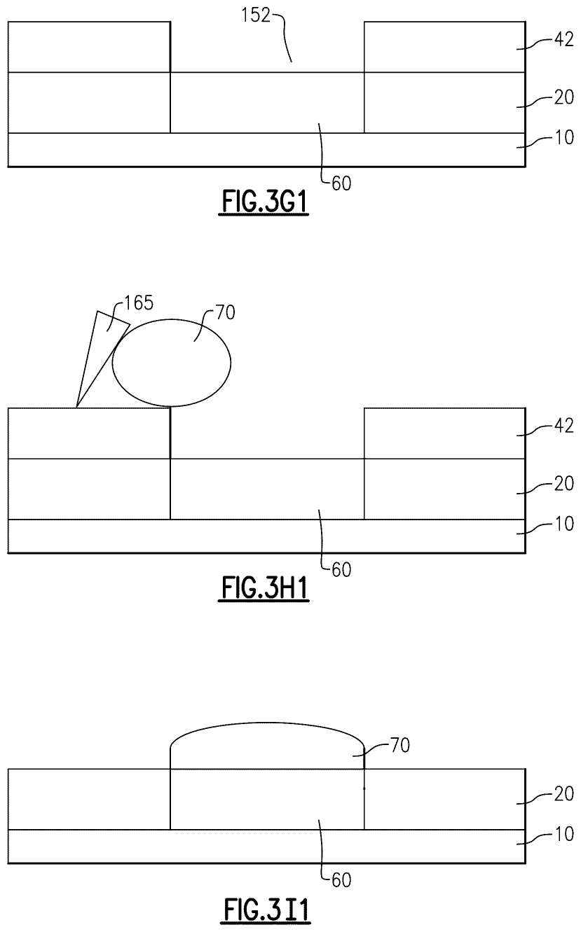

In the act illustrated in FIG. 1B, the layer of the first photoresist 20 is exposed, for example, by flood exposure to deep ultraviolet (DUV) light 30. A layer of a second photoresist 40 is then deposited on top of the layer of the first photoresist 20 (FIG. 1C.) In some implementations, the first photoresist 20 is PMGI, which is a DUV and E-beam photoresist. Photoresist 40 may be different from photoresist 20 and may be an i-line photoresist. The layer of the second photoresist 40 is exposed and developed to form an aperture 45 in the layer of the second photoresist 40 and to uncover a portion of the upper surface of the layer of the first photoresist 20 (FIG. 1D). The layer of the first photoresist 20 is then developed, which extends the aperture 45 downward through the layer of the first photoresist 20 to form a cavity 50 and uncover a portion of the upper surface of the wafer 10 beneath the portion of the layer of the second photoresist 40 that was previously developed (FIG. 1E). The uncovered portion of the upper surface of the wafer may include an electrical contact, for example, as illustrated in FIGS. 3A-3H below.

A layer of copper paste 60 is deposited into the cavity 50, for example, by vacuum assisted screen printing. The layer of copper paste 60 at least partially fills the cavity 50, e.g., a lower portion of the cavity 50, and contacts the previously uncovered portion of the upper surface of the wafer 10 (FIG. 1F). After sintering of the copper paste 60, which may be performed in a formic environment, a layer of solder paste 70 is deposited on top of the layer of copper paste 60, for example, by vacuum assisted screen printing (FIG. 1G). The layer of solder paste 70 fills the remainder of the cavity 50 that was not previously filled by the copper paste 60. No screen printing stencil is needed to screen print the copper paste 60 or solder paste 70.

In some embodiments, sintering of the copper paste 60 is performed before deposition of the solder paste 70. The Cu sintering temperature may be between 140° C. and 200° C., which is lower than the glass transition temperature (T_{g}) of the first and second photoresists 20, 40 and solder reflow may be formed at a temperature of between 220° C. and 250° C.

The layers of first and second photoresist 20, 40 are stripped (FIG. 1H) and the solder paste 70 reflowed to form a copper pillar with a cap of solder 70 with a dome-shaped upper surface (FIG. 1I). Accordingly, in some embodiments, the layers of first and second photoresist 20, 40 may remain present during the heating process in which the copper paste 60 is sintered and solder paste 70 reflowed and may be subsequently stripped. In other embodiments, the second photoresist 40 may be removed after patterning of the first photoresist 20, for example, between the acts shown in FIGS. 1E and 1F.

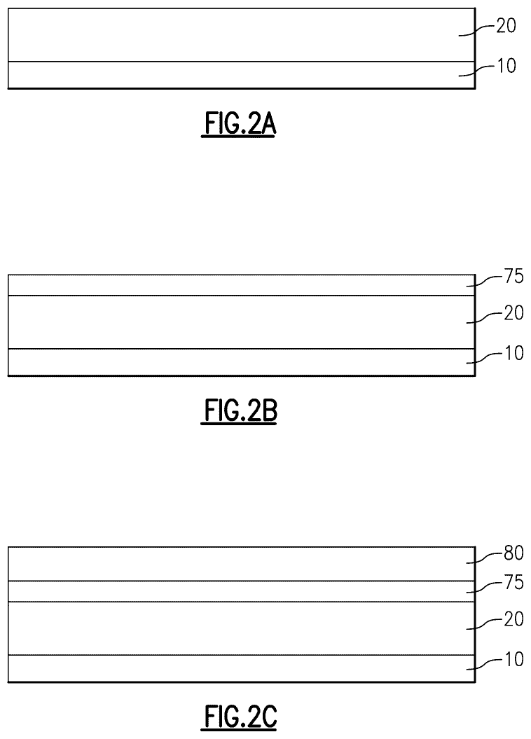

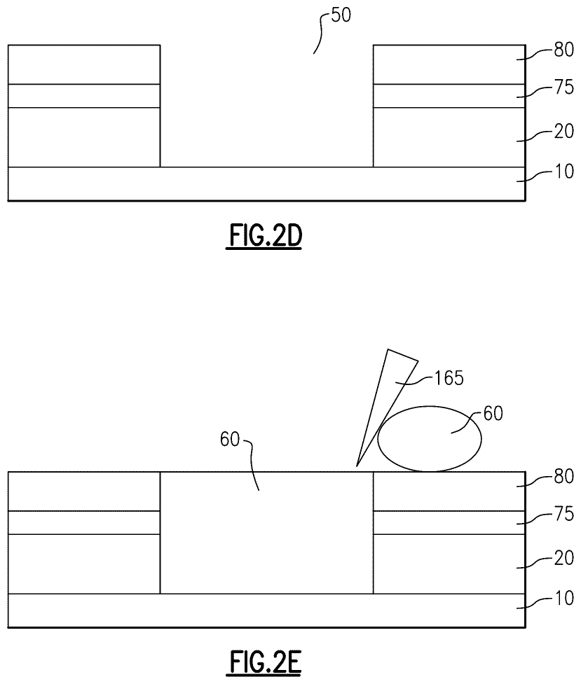

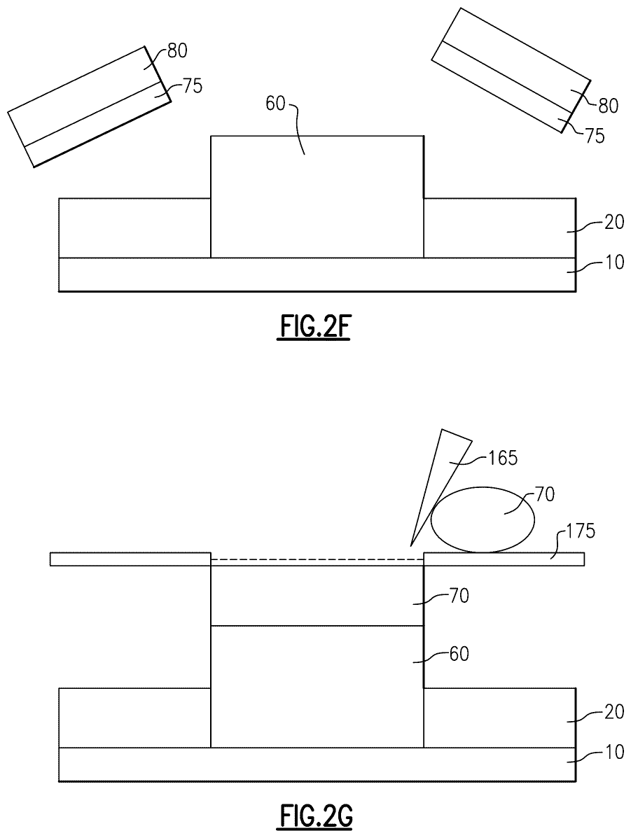

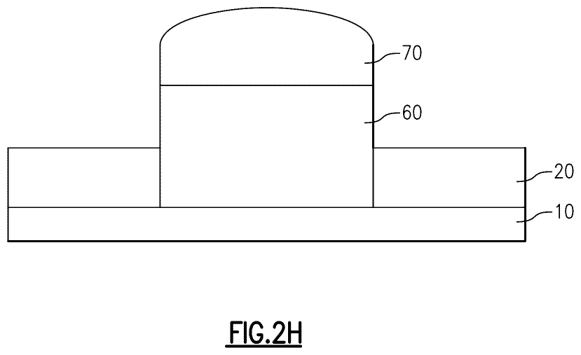

Another embodiment of a CPB formation process is illustrated in FIGS. 2A-2H. The act illustrated in FIG. 2A is similar to that illustrated in FIG. 1A—a semiconductor wafer 10, for example a GaAs, GaN, Si, InP, or other semiconductor wafer is provided and layer of photoresist 20 is deposited on the upper surface of the wafer 10. The photoresist 20 may be polyimide dry film photoresist and may be deposited by lamination or a spin on process as is known in the art. The layer of photoresist 20 may have a thickness of, for example, about 20-30 μm, although this thickness dimension may vary depending on the desired height of the copper pillar.

In the act shown in FIG. 2B, a layer of polyvinyl alcohol (PVA) 75 or other suitable polymer is spin coated or laminated on top of the layer of photoresist 20. An epoxy dry film 80 is then laminated on top of the layer of PVA 75. (FIG. 2C.) As will be explained later, the layer of PVA 75 forms a sacrificial layer or release layer for the epoxy dry film 80.

A cavity 50 where the copper pillar is to be formed is then defined by photolithographic patterning and developing (FIG. 2D) which is then filled with copper paste 60, for example, by vacuum assisted screen printing with a squeegee 165 (FIG. 2E). The copper paste 60 may then be solidified by sintering in a formic oven at a temperature of, for example, about 250° C.

Once the Cu paste 60 has been sintered, the PVA 75 and epoxy dry film may be peeled off (FIG. 2F). The sintered copper paste 60 forms a pillar with a height greater than that of the photoresist 20.

A layer of solder paste 70 may be screen printed on top of the copper pillar (FIG. 2G) and then reflowed at a temperature of, for example, about 250° C. to form a rounded top (FIG. 2H).

Another embodiment of a CPB formation process is illustrated in FIGS. 3A-3F. The act illustrated in FIG. 3A is similar to that illustrated in FIG. 1A—a semiconductor wafer 10, for example a GaAs, GaN, Si, InP, or other semiconductor wafer is provided and layer of photoresist 20 is deposited on the upper surface of the wafer 10. The photoresist 20 may be polyimide dry film photoresist and may be deposited by lamination or a spin on process as is known in the art. The layer of photoresist 20 may have a thickness of, for example, about 20-30 μm, although this thickness dimension may vary depending on the desired height of the copper pillar.

A cavity 50 where the copper pillar is to be formed is then defined by photolithographic patterning and developing (FIG. 3B) which is then filled with copper paste 60, for example, by vacuum assisted screen printing with a squeegee 165. (FIG. 3C.) The copper paste 60 may then be solidified by sintering in a formic oven at a temperature of, for example, about 250° C. to form a solidified copper pillar within the photoresist 20. (FIG. 3D.)

A dry etch may be performed to remove an upper portion of the photoresist 20 around the copper pillar so that an upper end of the copper pillar extends above an upper surface of the remaining photoresist 20. (FIG. 3E.)

A layer of solder paste 70 may be screen printed on top of the copper pillar with a squeegee 165 and stencil 175 (FIG. 3F) and then reflowed at a temperature of, for example, about 250° C. to form a rounded top (FIG. 3G).

It is to be appreciated that in some embodiments, the solder paste 70 may be deposited without the use of a stencil 175 as illustrated in FIG. 3F. It has been discovered that soler paste 70 does not wet materials such as polyimide when reflowed. Accordingly, instead of using a stencil 175 as illustrated in FIG. 3F to deposit the solder paste only on top of the copper pillars, a layer of solder paste 70 may be blanket deposited over the structure shown in FIG. 3E to form a structure such as illustrated in FIG. 3H. When the structure is heated to reflow the solder paste 70 the solder paste 70 will naturally migrate to regions on or around the exposed copper pillars and will not stick to the photoresist 20, resulting in the structure shown in FIG. 3G. This process may give superior results if the upper surfaces of the copper pillars are sputter cleaned prior to reflowing the solder paste 70.

In another embodiment, wave soldering may be utilized to deposit the solder on the copper pillars. (See FIG. 3I.) The molten solder will stick to the copper pillars but not to the photoresist 20 resulting in the structure of FIG. 3G.

In a modification to the process shown in FIGS. 3A-3G a plating resist, for example, 4620 plating resist (e.g., AZ® P4620 photoresist from Merck Performance Materials GmbH) may be utilized to define the dimensions of the solder cap on top of the copper pillar. The process modified process utilizes the same steps 3A-3D described above to result in the structure shown in FIG. 3D1 which is the same as that shown in FIG. 3D. Plating resist 42 may be deposited, for example, by spin coating on the structure shown in FIG. 3D1 as illustrated in FIG. 3E1. The plating resist 42 may be a positive photoresist, so areas of the plating resist 42 which are to be removed may be covered by a photomask 142 and the remaining portions of the photoresist exposed with, for example, g-, h- or i-line radiation 135 (approx. 320-440 nm). (FIG. 3F1). The portion of the plating resist 42 which is to be removed may be aligned over the sintered copper pillar 60, although in other embodiments, may have a greater or lesser width than that of the sintered copper pillar 60. The unexposed plating resist is developed and removed to form a cavity 152 above the sintered copper pillar 60 (FIG. 3G1). Solder paste 70 is deposited into the cavity, for example, with a squeegee 165, optionally under vacuum conditions (FIG. 3HI). The remainder of the plating resist 42 is stripped and the solder paste 70 reflowed to form the solder cap on top of the sintered copper pillar (FIG. 3I1).

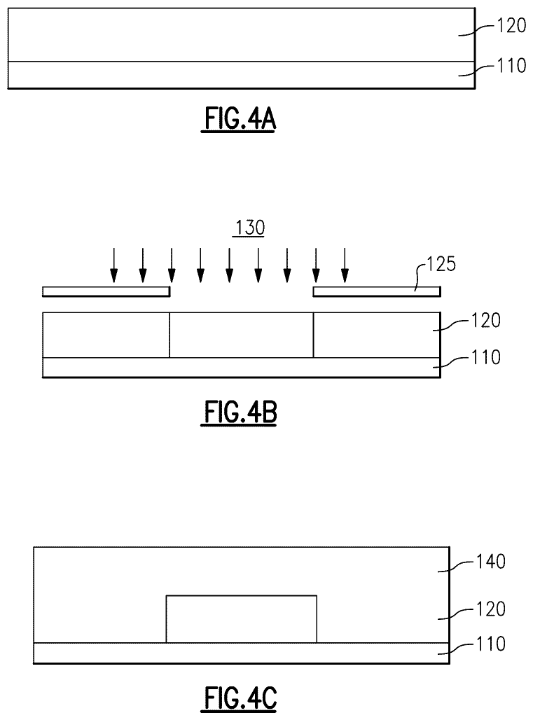

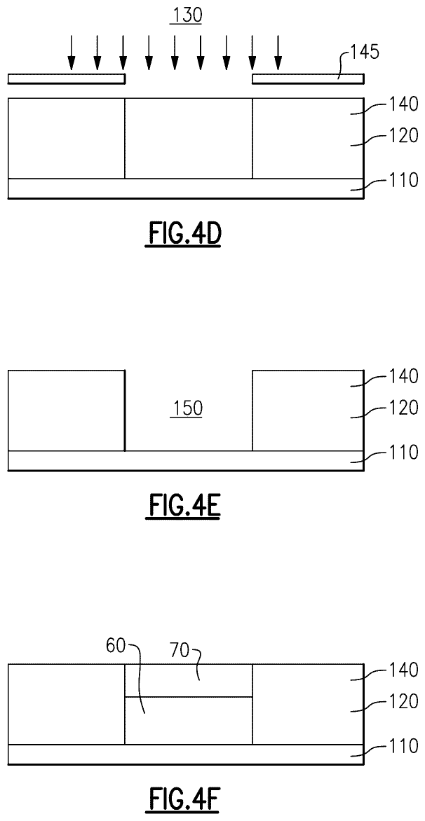

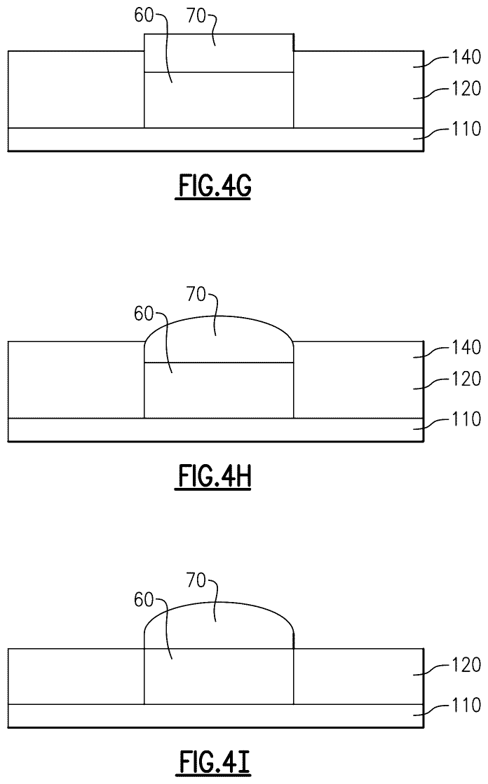

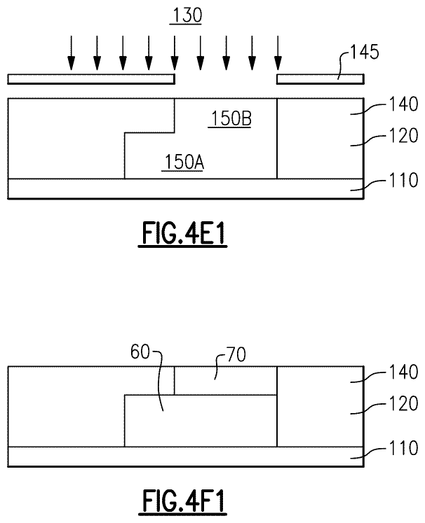

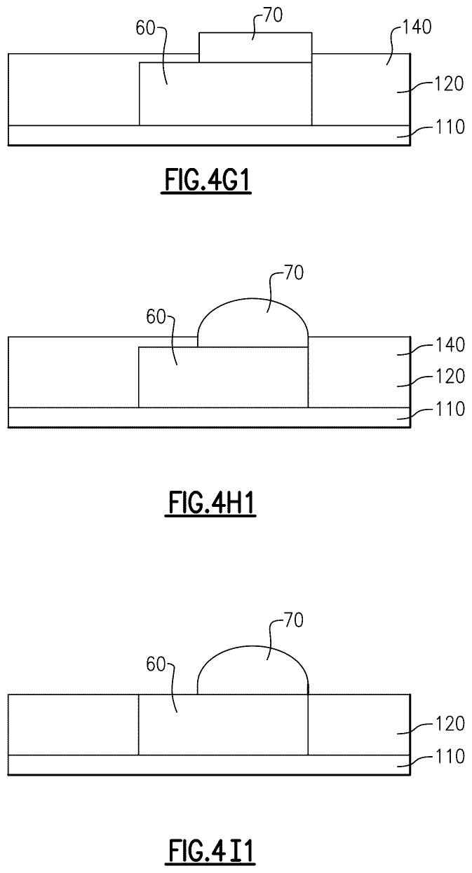

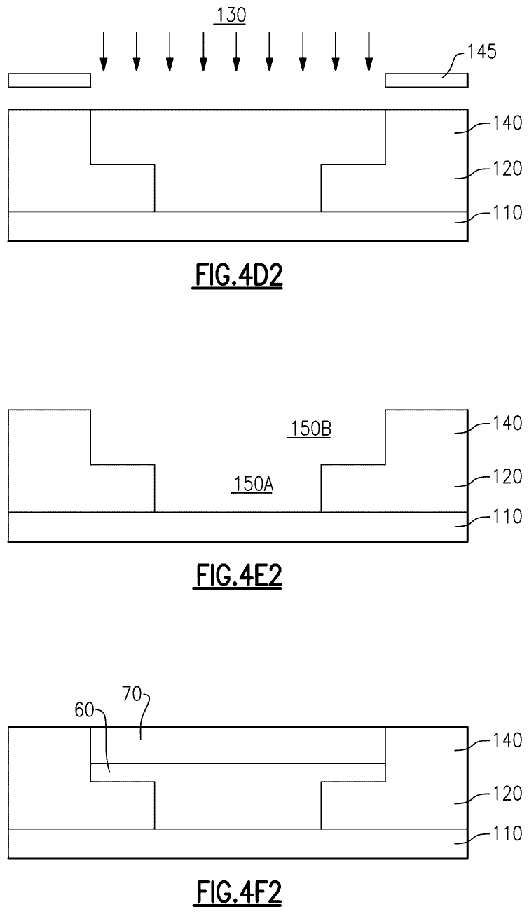

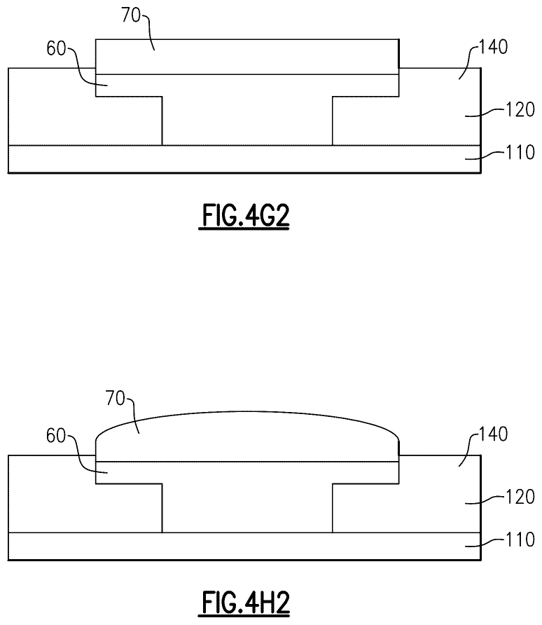

Another embodiment of a CPB formation process is illustrated in FIGS. 4A-4H. The act illustrated in FIG. 4A is similar to that illustrated in FIG. 1A—a semiconductor wafer 110, for example a GaAs, GaN, Si, InP, or other semiconductor wafer is provided and layer of a first photoresist 120 is deposited on the upper surface of the wafer 110. The first photoresist 120 may be polyimide dry film photoresist and may be deposited by lamination or a spin on process as is known in the art. The layer of the first photoresist 120 may have a thickness of, for example, about 20 μm, although this thickness dimension may vary depending on the desired height of the copper pillar.

In the act illustrated in FIG. 4B, a mask 125 is provided and an aperture in the mask 125 is aligned with the location on the wafer 110 and first photoresist 120 where the copper pillar is to be formed. The layer of the first photoresist 120 is exposed through the aperture in the mask 125, for example, utilizing i-line light 130.

As illustrated in FIG. 4C, a layer of a second photoresist 140, which may be the same material as that of the first photoresist 120 or a plating resist, is then deposited on the upper surface of the first photoresist 120 over both the exposed and unexposed portions of the first photoresist 120. The layer of the second photoresist 140 may have a similar or same thickness as that of the layer of the first photoresist 120, for example, about 20 μm, although in other examples, the thicknesses of the layers of the first and second photoresists 120, 140 may differ. Another mask 145, which in some embodiments may be the same mask as the mask 125, is provided and an aperture in the mask 145 is aligned with the location on the wafer 110 and first and second photoresists 120, 140 where the copper pillar is to be formed. The first photoresist 120 may have a ghost image after exposure to which the mask 145 for the layer of second photoresist 140 may be aligned. The layer of the second photoresist 140 is exposed through the aperture in the mask 145, for example, utilizing i-line light 130 (FIG. 4D). In some examples, the acts illustrated in FIGS. 4C and 4D may be omitted, and the first photoresist 120 deposited with a thickness corresponding to the sum of the thicknesses of the first photoresist 120 and second photoresist 140.

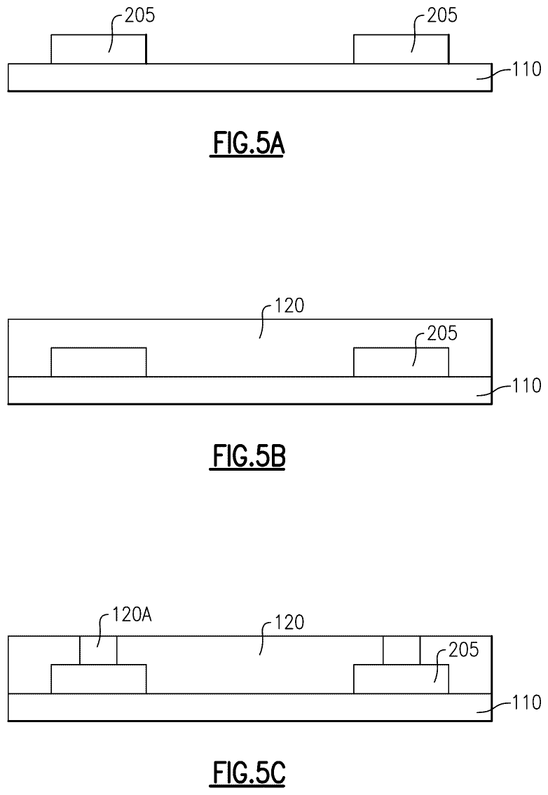

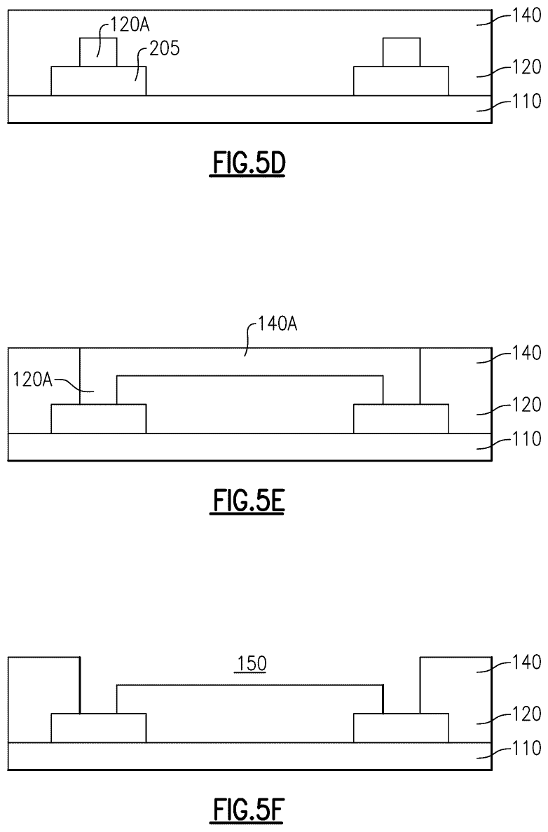

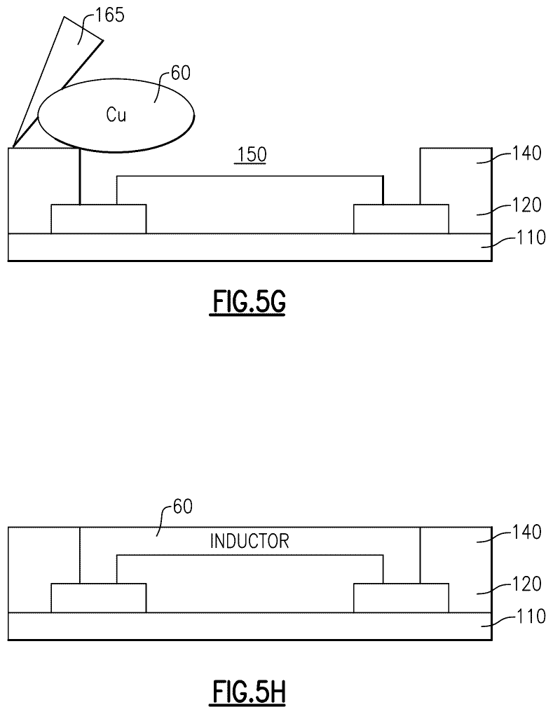

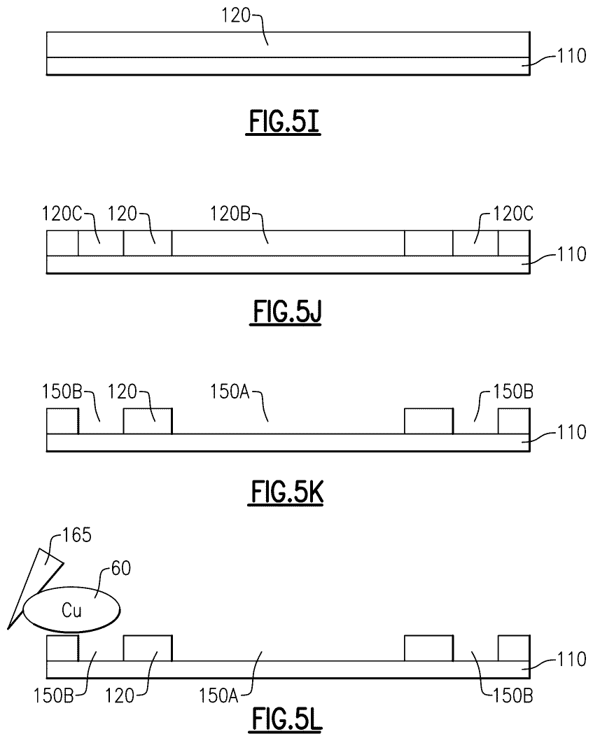

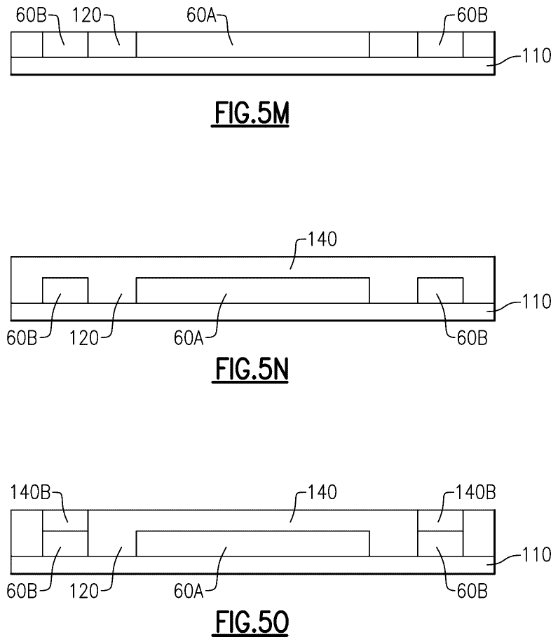

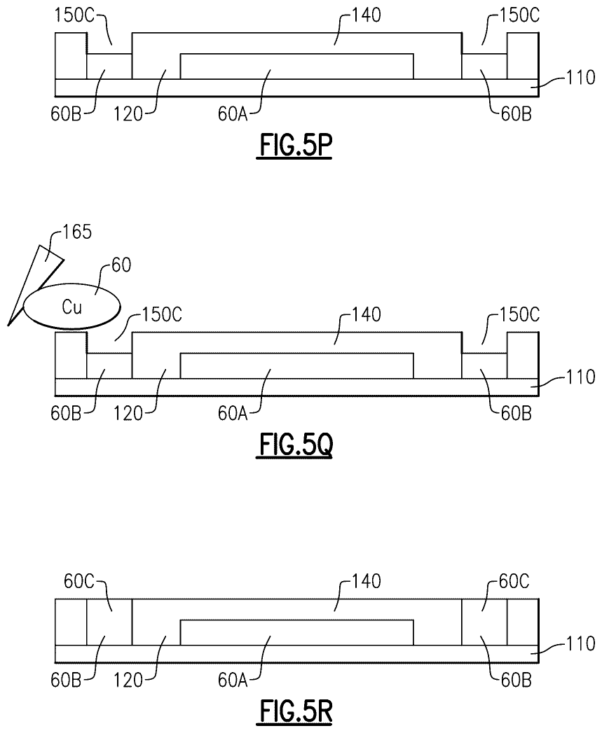

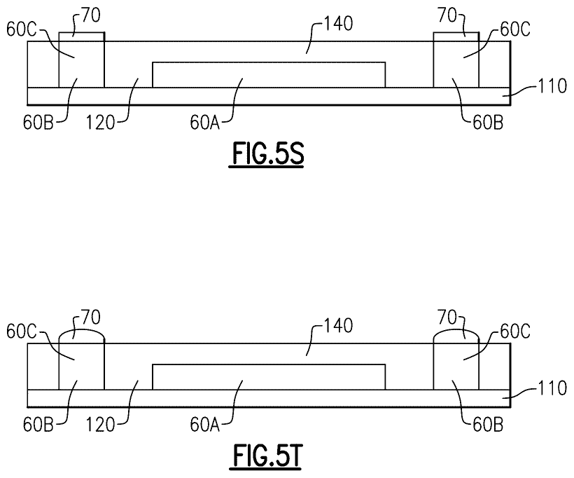

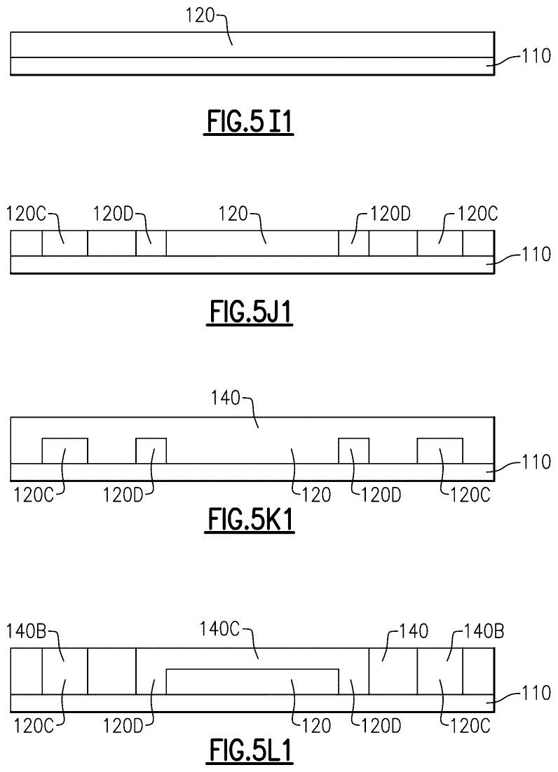

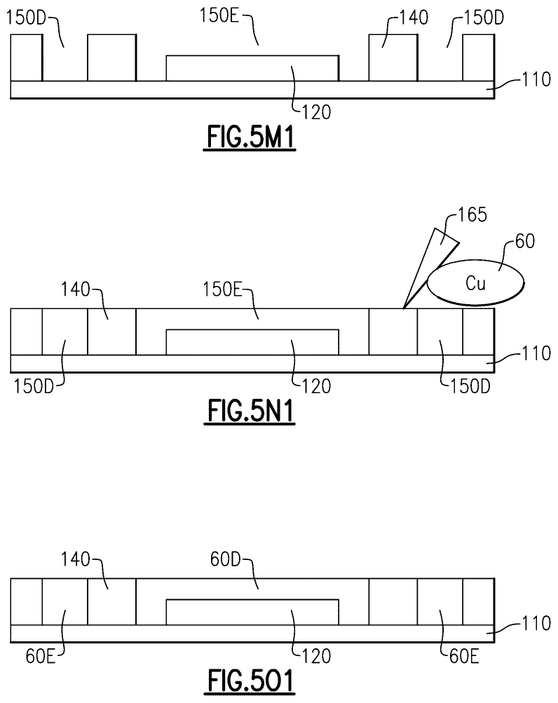

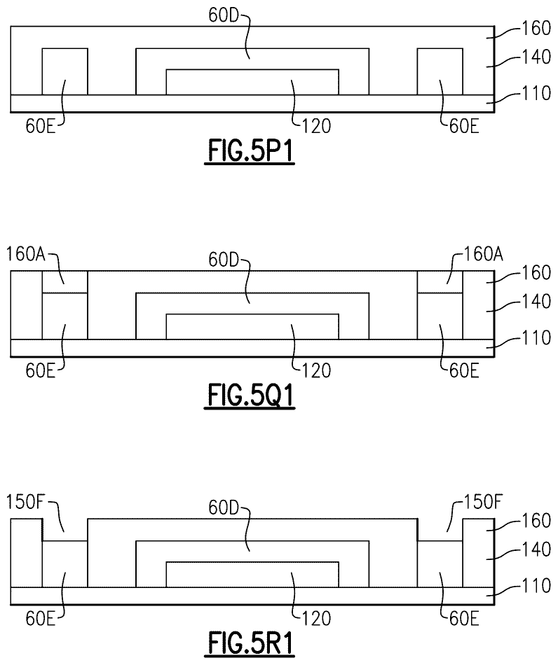

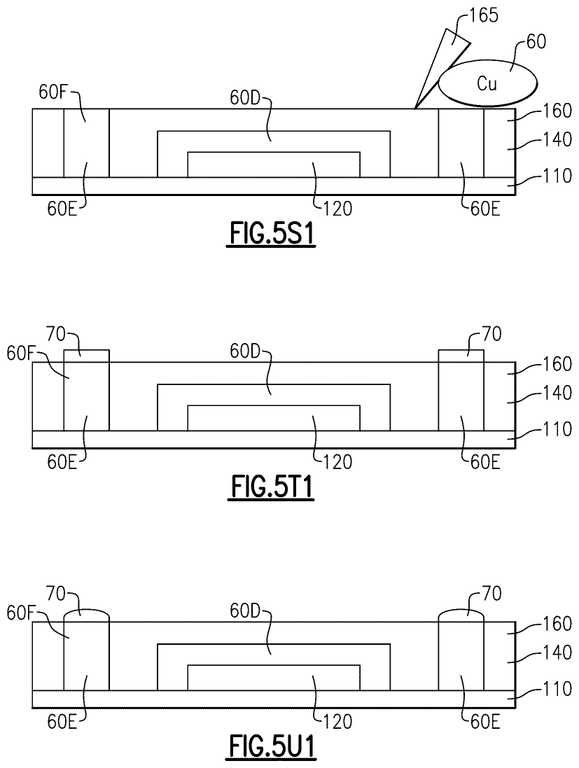

The layers of the first and second photoresist 120, 140 are developed, resulting in a cavity 150 being formed where the first and second photoresist 120, 140 had been exposed (FIG. 4E). The cavity 150 exposes a portion of the upper surface of the wafer 110 that may include an electrical contact such as a contact 205 illustrated in FIG. 5A below. A layer of copper paste 60 is deposited in the cavity, followed by a layer of solder paste 70 by, for example, vacuum assisted screen printing (FIG. 4F). No screen printing stencil is needed to screen print the copper paste 60 or solder paste 70. The upper surface of the solder paste 70 may be flush with the upper surface of the layer of the second photoresist 140 after initially being deposited. The copper paste 60 may be sintered prior to depositing the solder paste 70.

The copper paste 60 may be sintered by placing the structure shown in FIG. 4F in a formic environment at an appropriate temperature, e.g., between 120° C. and 300° C. or between 140° C. and 200° C. for an appropriate time, e.g., between 30 minutes and two hours. After sintering the copper paste 60 an upper portion of the layer of second photoresist 140 may be removed by etching to uncover a portion of the layer of solder paste 70 above the upper surface of the partially etched layer of second photoresist 140 (FIG. 4G) after which the solder paste 70 may be reflowed to form a copper pillar with a cap of solder 70 with a dome-shaped upper surface (FIG. 4H). The remainder of the layer of second photoresist 140 may then be stripped, as illustrated in FIG. 4I. Alternatively, the solder paste 70 may be reflowed prior to removing any of the layer of second photoresist 140.

A variation on the process illustrated in FIGS. 4A-4I is illustrated in FIG. 4E1-4I1. After deposition of the layer of the second photoresist 140 as shown in FIG. 4C, the process may proceed to the act illustrated in FIG. 4E1 rather than that illustrated in FIGS. 4D and 4E. As shown in FIG. 4E1, the mask 145 is aligned such that the aperture in the mask is laterally offset from the exposed portion of the layer of the first photoresist 120. Exposure of the layers of photoresist 120, 140 through the aperture in the mask 145 results in exposure of a portion of the second photoresist 140 that is laterally offset and/or that has a different shape or pitch from the previously exposed portion of the first photoresist 120. An additional portion of the first photoresist 120 that is laterally offset and/or that has a different shape or pitch from the previously exposed portion of the first photoresist 120 may also be exposed as shown in FIG. 4E1. After development of the layers of photoresist 120, 140 the resultant cavity may include a lower portion 150A and an upper portion 150B, wherein the upper portion 150B has a sidewall laterally offset from a sidewall of the lower portion 150A and the upper portion 150B does not entirely overlap the lower portion 150A.

The process proceeds as illustrated in FIG. 4F1-4I1, which correspond to the acts shown in FIGS. 4F-4I, the details of which are not repeated herein. The resulting structure shown in FIG. 4I1 includes a copper pillar with a cap of solder 70 having a dome-shaped upper surface wherein the copper pillar portion of the CPB is wider than the solder portion and the solder portion does not cover the entirety of the copper portion.

Another variation on the process illustrated in FIGS. 4A-4H is illustrated in FIG. 4D2-4H2. After deposition of the layer of the second photoresist 140 as shown in FIG. 4C, the process may proceed to the act illustrated in FIG. 4D2 rather than that illustrated in FIG. 4D. As shown in FIG. 4D2, the mask 145 is aligned such that the aperture in the mask laterally extends outward from both sides over the exposed portion of the layer of the first photoresist 120. Exposure of the layers of photoresist 120, 140 through the aperture in the mask 145 results in exposure of a portion of the second photoresist 140 that has a greater width than the previously exposed portion of the first photoresist 120. The exposed portion of the second photoresist 140 may be above, covering, and surrounding the previously exposed portion of the first photoresist 120. The previously exposed portion of the first photoresist 120 may be centered under the exposed portion of the second photoresist 140. The second exposure may cause sidewalls around the previously exposed portion of the first photoresist 120 to be exposed, leading to the exposed portion of the first photoresist 120 to have tapered sidewalls rather than vertical sidewalls as illustrated in FIG. 4D2. After development of the layers of photoresist 120, 140 the resultant cavity may include a lower portion 150A and an upper portion 150B, wherein the upper portion 150B overlaps and has a greater width than the lower portion 150A. In some embodiments, the lower portion 150A may be centered below the upper portion 150B.

In the act shown in FIG. 4F1 a layer of copper paste 60 is deposited in the cavity, followed by a layer of solder paste 70 by, for example, vacuum assisted screen printing. In some embodiments, the layer of copper paste 60 may fill a portion of the upper wider cavity 150B as well as the lower cavity 150A. No screen printing stencil is needed to screen print the copper paste 60 or solder paste 70. The upper surface of the solder paste 70 may be flush with the upper surface of the layer of the second photoresist 140 after initially being deposited.

The process proceeds as illustrated in FIG. 4G2 and 4H2, which correspond to the acts shown in FIGS. 4G and 4H, the details of which are not repeated herein. The resulting structure shown in FIG. 4H2 includes a copper pillar with a cap of solder 70 having a dome-shaped upper surface wherein the solder portion of the CPB is wider than the lower copper portion.

It is to be appreciated that the process presented in FIG. 4D2-4H2 may alternatively be used to form an upper layer of copper with a lesser width than the lower layer of copper by forming the upper portion 150B of the cavity with a lesser width than the lower portion 150A.

The process described with reference to FIGS. 4A-4H, or the alternative to same including the acts shown in FIG. 4E1-4H1 or FIG. 4D2-4H2 may be utilized to form not only CPBs, but also other structures such as inductors, baluns, redistribution layers, heat sinks or heat spreaders, hermetic seal rings, etc. As illustrated in FIG. 5A, a semiconductor wafer 110, for example a GaAs, GaN, Si, InP, or other semiconductor wafer is provided. The semiconductor wafer 110 includes two electrical contacts 205 that will serve as terminals for an inductor or a redistribution layer to be formed. As illustrated in FIG. 5B, a layer of a first photoresist 120 is deposited on the upper surface of the wafer 110. The first photoresist 120 may be polyimide dry film photoresist and may be deposited by a spin on process as is known in the art in a similar manner as photoresist is deposited as depicted in FIGS. 1A and 2A above. In the act illustrated in FIG. 5C regions 120A of the first photoresist 120 that are disposed over the electrical contacts 205 are exposed, for example, using a mask such as illustrated in FIG. 2B above. A layer of a second photoresist 140, which may be the same material as that of the first photoresist 120, is then deposited on the upper surface of the first photoresist 120 over both the exposed and unexposed portions of the first photoresist 120 as shown in FIG. 5D in a similar manner as depicted in FIG. 4C above. A portion 140A of the second photoresist 140 is then exposed as shown in FIG. 5E utilizing a mask such as in the act depicted in FIG. 4D or 4E1 above. The exposed portion 140A of the second photoresist 140 includes areas disposed on top of the previously exposed portions 120A of the first photoresist 120 and extends from one of the previously exposed portions 120A of the first photoresist 120 to the other of the previously exposed portions 120A of the first photoresist 120. The exposed portion 140A of the second photoresist 140 may include spiral shaped portions when viewed from above to define the shape of the inductor to be formed, or an appropriate pattern for a redistribution layer to be formed. The exposed portions 120A, 140A of the first and second photoresists 120, 140 are then developed, which defines a trench or cavity 150 extending from one of the previously exposed portions 120A of the first photoresist 120 to the other of the previously exposed portions 120A of the first photoresist 120 (FIG. 5F). A conductive metal paste, such as copper paste 60 is then deposited on top of the structure illustrated in FIG. 5F and pushed into the trench/cavity 150 with a squeegee 165 as shown in FIG. 5G. The copper paste 60 is subsequently sintered and forms an inductor or redistribution layer with ends connected to the electrical contacts 205 as illustrated in FIG. 5H. In other embodiments, the structure labelled as an inductor in FIG. 5H may alternatively be another three dimensional structure, for example, a balun or portion thereof.

In some embodiments, concurrently with forming the inductor, redistribution layer, or balun in the method illustrated in FIGS. 5A-5H, copper pillars 60′, 70′ may be formed in other areas of the die by patterning and screen printing into the same first and second photoresists 120, 140 as used to form the inductor, redistribution layer, or balun in accordance with any one or more of the processes disclosed herein.

In a modification to the process shown in FIGS. 5A-5H, an inductor, balun, or other circuit element or conductive trace may be formed by screen printing of copper paste within a pattern defined in the layer of the first photoresist 120 concurrently with forming lower portions of copper pillars in other cavities defined in the layer of the first photoresist 120. After sintering of the circuit element and lower portions of the copper pillars, the layer of second photoresist 140 may then be deposited on the circuit element, lower portions of the copper pillars, and the layer of the first photoresist 120 and patterned to define cavities into which additional copper paste may be screen printed and sintered to define the upper portions of the copper pillars. Solder paste may be screen printed on top of the sintered additional copper paste to define solder caps on top of the copper pillars. This modified process is illustrated in FIG. 5I-5T.

FIG. 5I illustrates the layer of the first photoresist 120 deposited on the upper surface of the wafer 110. FIG. 5J illustrates that region 120B and regions 120C in the first photoresist 120 are exposed, for example, using a mask such as illustrated in FIG. 2B above. Region 120B is formed in the shape of the inductor, balun, or other circuit element that will be formed in this region. Regions 120C are formed in the shape of lower portions of copper pillars to be formed in these regions. As shown in FIG. 5K, exposed regions 120B and 120C of the first photoresist 120 are developed and removed to define cavities 150A and 150B for the circuit element and lower portions of copper pillars, respectively. In the act shown in FIG. 5L, copper paste 60 is deposited with a squeegee 165, optionally utilizing vacuum assisted screen printing, into cavities 150A and 150B. The deposited copper paste is then sintered in a formic environment to form the circuit element 60B and lower portions of the copper pillars 60C (FIG. 5M). A layer of a second photoresist 140, which may be the same material as that of the first photoresist 120, is then deposited on the upper surface of the first photoresist 120, the circuit element 60B and lower portions of the copper pillars 60C (FIG. 5N). Regions 140B in the second photoresist 140 where upper portions of the copper pillars are to be formed are then exposed, for example, using a photomask (FIG. 5O) and then developed and removed to define cavities 150C in the second photoresist 140 over the lower portions of the copper pillars (FIG. 5P). Additional copper paste 60 is deposited with a squeegee 165, optionally utilizing vacuum assisted screen printing, to fill the cavities 150C in the second photoresist 140 (FIG. 5Q) and is sintered in a formic environment to form upper copper portions 60C of the copper pillars (FIG. 5R). Solder paste 70 is then deposited with a squeegee or by other methods as disclosed herein on the upper copper portions 60C of the copper pillars (FIG. 5S). The deposited solder paste 70 is then reflowed to form solder caps on top of the copper pillars (FIG. 5T).

It is to be appreciated that the steps shown in FIGS. 5I-5T may be modified to form an inductor or redistribution layer above the surface of the wafer 110 as illustrated in FIGS. 5A-5H rather than or in addition to a circuit element disposed directly on the wafer 110. This modified process begins with the same act as shown in FIG. 5I above—a first layer of photoresist 120 deposited on the upper surface of the wafer 110 (FIG. 5I1). As shown in FIG. 5J1, regions 120C and regions 120D in the first layer of photoresist 120 are exposed, for example, using a mask such as illustrated in FIG. 2B above. Regions 120C are formed in the shape of lower portions of copper pillars to be formed in these regions. Regions 120D are formed in the shape of lower portions of a circuit element, for example, an inductor, balun, or other circuit element that will be formed in these regions.

A layer of a second photoresist 140, which may be the same material as that of the first photoresist 120, is then deposited on the upper surface of the first layer of photoresist 120 and over regions 120C and 120D (FIG. 5K1). As shown in FIG. 5L1, regions 140B and regions 140C in the second layer of photoresist 140 are exposed, for example, using a mask such as illustrated in FIG. 2B above. Regions 140B are formed in the shape of intermediate portions of copper pillars to be formed in these regions. Region 140C is formed in the shape of an upper portion of a circuit element, for example, an inductor, balun, or other circuit element that will be formed in this region. As shown in FIG. 5M1, exposed regions 120C and 120D of the first layer of photoresist 120 and regions 140B and 140C of the second layer of photoresist 140 are developed and removed to define cavities 150D and 150E for the lower portions of copper pillars and for the circuit element, respectively. In the act shown in FIG. 5N1, copper paste 60 is deposited with a squeegee 165, optionally utilizing vacuum assisted screen printing, into cavities 150D and 150E. The deposited copper paste is then sintered in a formic environment to form the circuit element 60D and lower portions of the copper pillars 60E (FIG. 5O1).

A third layer of photoresist 160, which may be the same material as that of the first layer of photoresist 120 and/or second layer of photoresist 140, is then deposited on the upper surface of the second layer photoresist 140, the circuit element 60D and lower portions of the copper pillars 60E (FIG. 5P1). Regions 160A in the third layer of photoresist 160 where upper portions of the copper pillars are to be formed are then exposed, for example, using a photomask (FIG. 5Q1) and then developed and removed to define cavities 150F in the third layer of photoresist 160 over the lower portions of the copper pillars (FIG. 5R1). Additional copper paste 60 is deposited with a squeegee 165, optionally utilizing vacuum assisted screen printing, to fill the cavities 150F in the third layer of photoresist 160 (FIG. 5S1) and is sintered in a formic environment to form upper copper portions 60F of the copper pillars. Solder paste 70 is then deposited with a squeegee or by other methods as disclosed herein on the upper copper portions 60F of the copper pillars (FIG. 5T1). The deposited solder paste 70 is then reflowed to form solder caps on top of the copper pillars (FIG. 5U1).

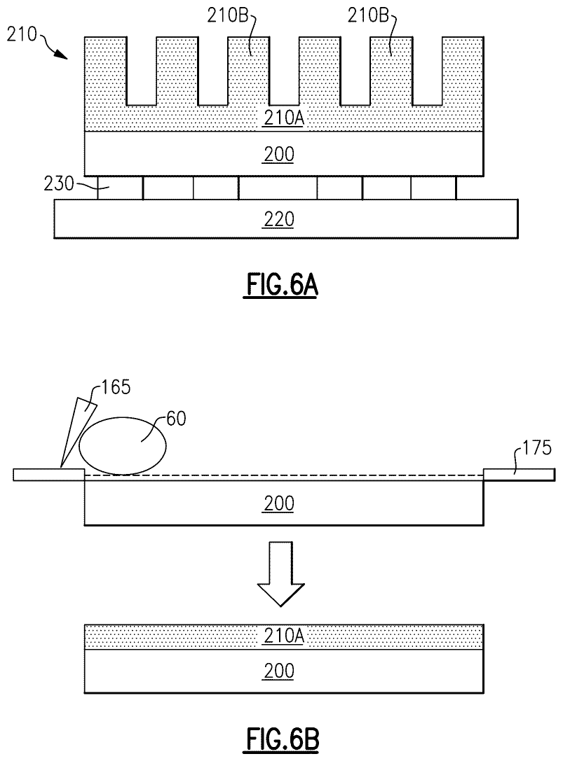

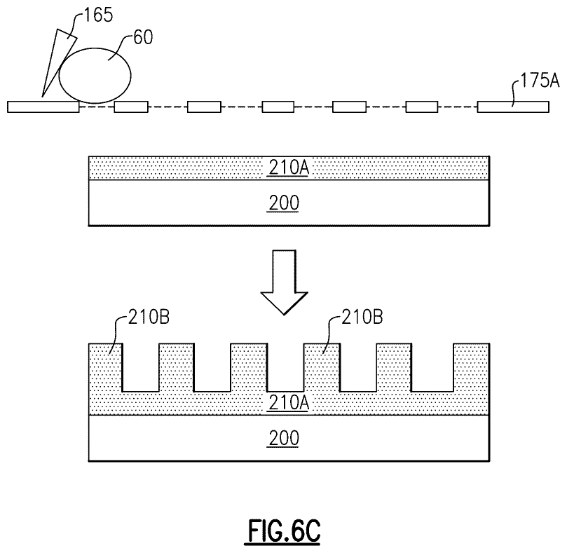

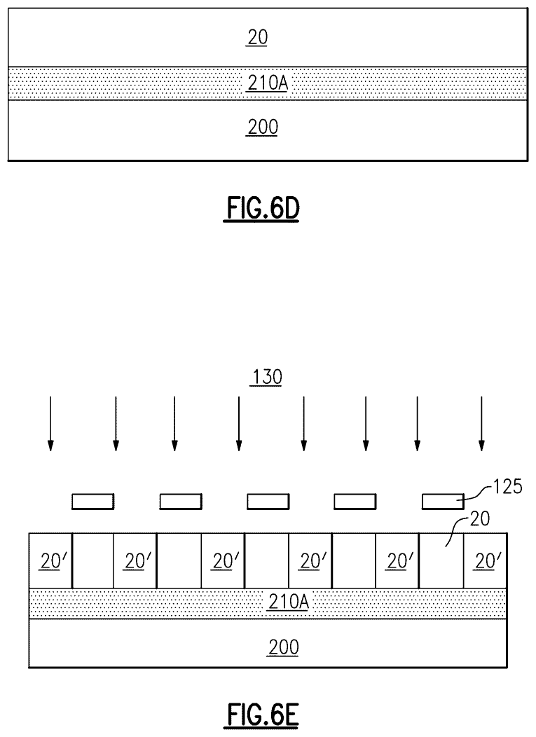

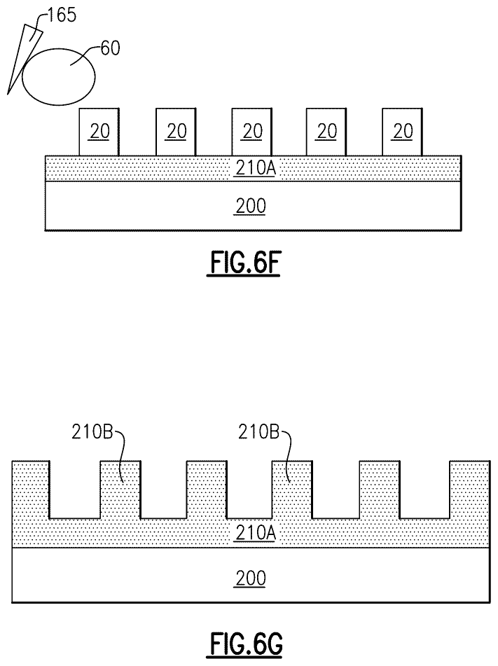

A method of forming a heat spreader utilizing copper paste deposition is illustrated in FIG. 6A-6G. A heat spreader 210 may in some embodiments be useful to assist in the dissipation of heat from a semiconductor die. FIG. 6A illustrates an example of a heat spreader 210 including a base 210A and multiple fins 210B mounted to the rear of a die 200 that is in turn flip chip mounted onto a carrier substrate 220, for example, a printed circuit board or multi-chip module using solder bumps or pillars 230. This is only one example of an implementation of a heat spreader 210. It is to be understood that heat spreaders 210 as disclosed herein may be utilized in multiple alternative implementations.

To form the heat spreader 210 a layer of copper paste 60 to form the base 210A is deposited onto a surface of a die 200 (or semiconductor substrate), for example, the rear side surface of the die 200. The layer of copper paste 60 used to form the base 210A may be a contiguous layer of copper paste. The copper paste 60 may be deposited using a screen or stencil 175 and squeegee 165 as illustrated in FIG. 6B. The screen or stencil 175 may be unnecessary if the entirety of the rear of the die 200 is to be covered in the copper paste 60.

The copper paste 60 forming the base 210A of the heat spreader is then sintered in a formic environment at an appropriate temperature, e.g., between 120° C. and 300° C. or between 140° C. and 200° C. for an appropriate time, e.g., between 30 minutes and two hours to form a solid layer.

The fins 210B are then deposited on the base 210A. The fins 210B may be deposited on the base 210A utilizing another screen or stencil 175A with apertures in the desired shapes for the fins 210B, for example, rectangular apertures, and squeegee 165 as illustrated in FIG. 6B. In some embodiments, the screen printing process illustrated in FIG. 6C may be capable of depositing fins 210B with heights of up to 50 μm. If this fin height is acceptable, the fins 210B may be sintered after deposition and the heat spreader 210 may be complete. If a greater fin height is desired, the screen printing process illustrated in FIG. 6C may be repeated to build up the fins 210B to a desired height. The deposited portions of the fins 210B should be sintered prior to additional fin layers being added.

In an alternative method, the fins 210B may be formed in apertures defined in a photoresist, for example, polyimide, deposited on the base 210A of the heat spreader. For example, after the base 210A of the heat spreader 210 is deposited on the die 200 in a process such as illustrated in FIG. 6B and sintered, a layer of photoresist 20 may be deposited on top of the sintered base portion 210 as illustrated in FIG. 6D. A photo mask 125 is then used to define areas of the photoresist 20 that are to be exposed to radiation, for example, ultraviolet radiation 130 (FIG. 6E). If a positive photoresist 20 is used exposed areas 20′ of the photoresist will be made soluble and able to be removed in a developer. If a negative positive photoresist 20 is used exposed areas 20′ of the photoresist will be made insoluble while unexposed areas will be able to be removed in a developer. The portions of the photoresist occupying areas where it is desired to form the fins 210B of the heat spreader are removed by developing the photoresist to define cavities 20A (FIG. 6F). Copper paste 60 is then deposited in the apertures with, for example, a squeegee 165 under vacuum so that air bubbles are not trapped in the deposited copper paste 60 (FIG. 6F). No screen or stencil may be required to deposit the copper paste 60 for the fins 210B. The fins 210B are then sintered and the remaining photoresist 20 removed to form a completed heat spreader as illustrated in FIG. 6G.

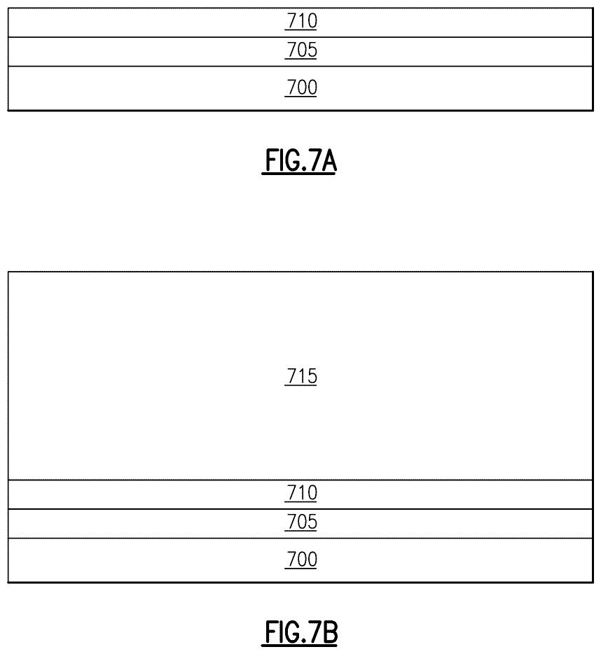

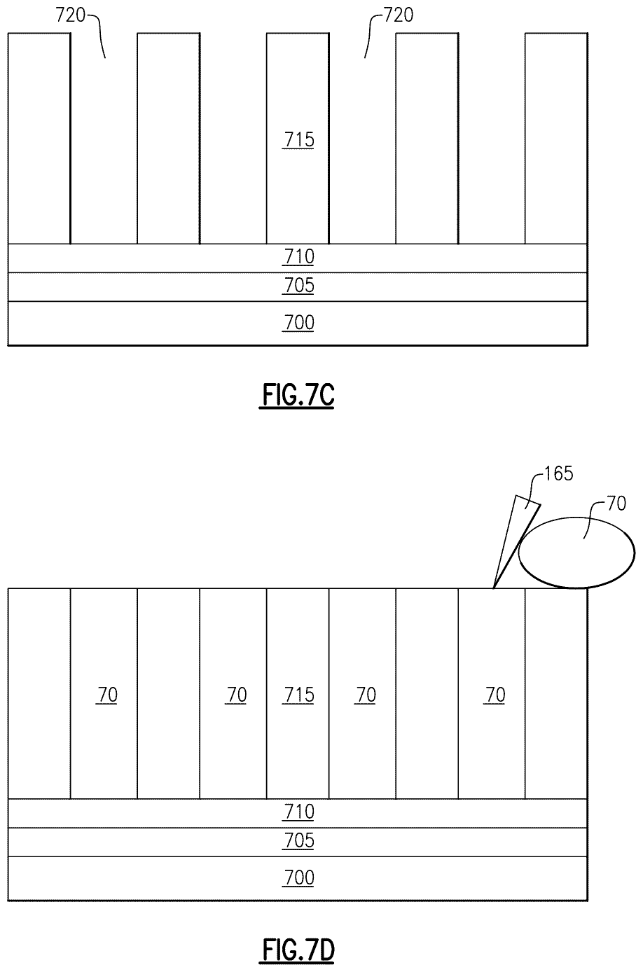

An alternate method of forming a heat spreader from copper paste involves forming the heat spreader removably on a sacrificial substrate from which the heat spreader may be removed and applied to a device, for example, by a pick and place process. This alternate method begins with coating the upper surface of carrier wafer 700, for example, a silicon wafer, with a layer of polyimide 705. A layer of polyvinyl alcohol (PVA) 710 is the coated on top of the layer of polyimide 705. (FIG. 7A.) A layer of dry film resist 715 having a thickness the same as the desired thickness of the heat spreader is laminated on top of the layer of PVA 710. (FIG. 7B.) The layer of dry film resist 715 is photolithographically patterned and developed to define cavities 720 that will be filled with copper paste to form the heat spreader. (FIG. 7C.) Copper paste 60 is then deposited into the cavities 720, for example, with a squeegee 165, optionally in a vacuum assisted screen printing process. (FIG. 7D.) The copper paste 60 is sintered to form the heat spreader and the dry film resist 715 is stripped. (FIG. 7E.) The upper surface of the layer of PVA 710 is exposed by stripping the dry film resist 715. The layer of PVA 710 may be dissolved and the heat spreader removed from the carrier wafer 700 and attached to a device for use.

The copper bodies formed in the process illustrated in FIGS. 7A-7E may be used for alternative process in addition to or as an alternative to forming a heat spreader. The copper bodies may be formed in the shape of plates or rods and removed and applied, for example, by a pick and place process, into a multi-component module, for example, into molding between devices in the module, to function as electromagnetic shielding between devices in the module or between area outside of the module and devices within the module.

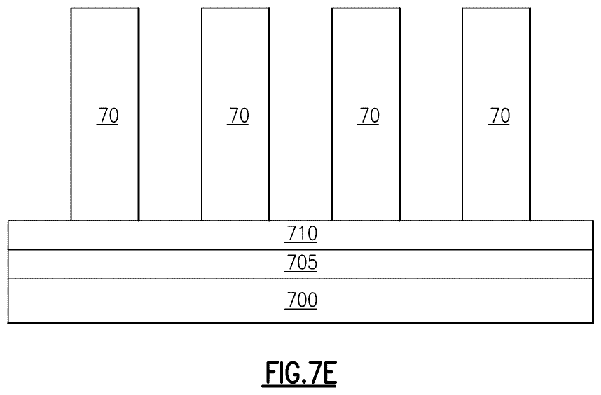

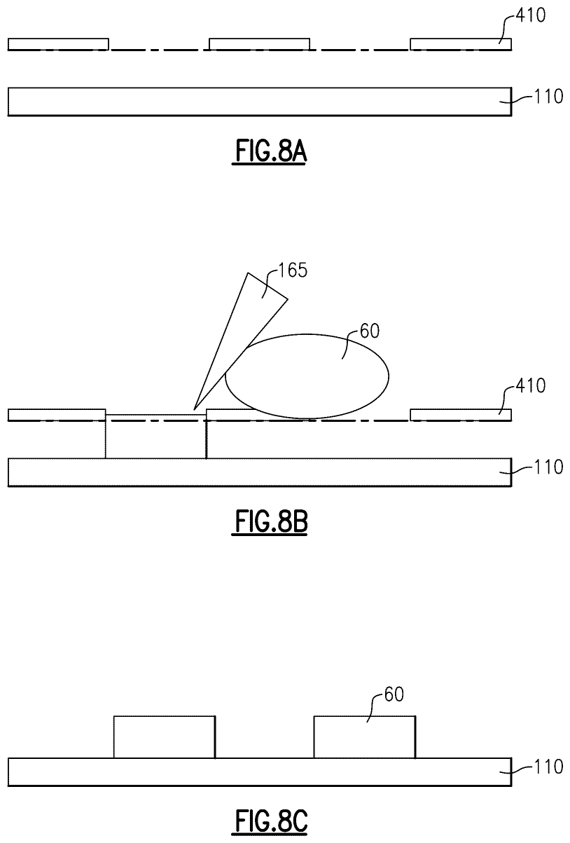

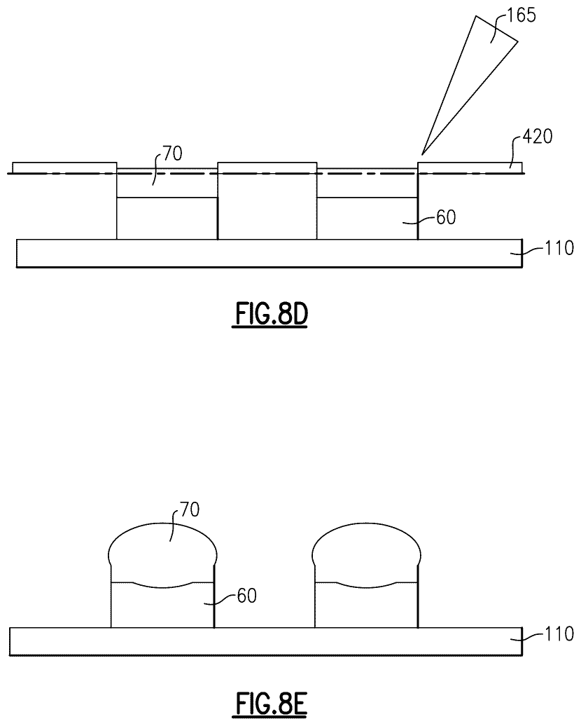

In accordance with another aspect of the present disclosure, CPBs may be formed on the surface of a semiconductor wafer or die without the need for photoresist or photolithography to define the dimensions of the CPBs. Rather, copper paste and solder paste may be directly screen printed onto a wafer with the dimensions of the CPBs defined by the stencil used to perform the screen printing and its placement relative to the wafer during the screen printing process. A screen printing process can have line resolution of better than 20 μm and is adequate for the large geometry of copper pillars, and may also be used for fast prototyping or proof of concept for new designs. Examples of acts in such a process are illustrated in FIGS. 8A-8E. As shown in FIG. 8A a screen print stencil 410 is aligned above a wafer 110 with apertures in the stencil 410 aligned to areas where the CPBs are to be formed. Thickness of the stencil 410 and sizes of apertures in the stencil may define the height of the copper pillars to be deposited. Copper paste 60 is deposited on top of the stencil 410 and a squeegee 165 is used to push the copper paste 60 through apertures in the stencil 410 and on to the wafer 110 as shown in FIG. 8B. The copper paste 60 is sintered to form the copper pillars (FIG. 8C). A solder paste screen print stencil 420 is then placed above the wafer 110 and copper pillars with apertures in the solder paste screen print stencil 420 aligned to the copper pillars and another squeegee 165 is used to push solder paste 70 through the apertures in the solder paste screen print stencil 420 on top of the copper pillars (FIG. 8D). The solder paste 70 is reflowed to complete the CPBs (FIG. 8E).

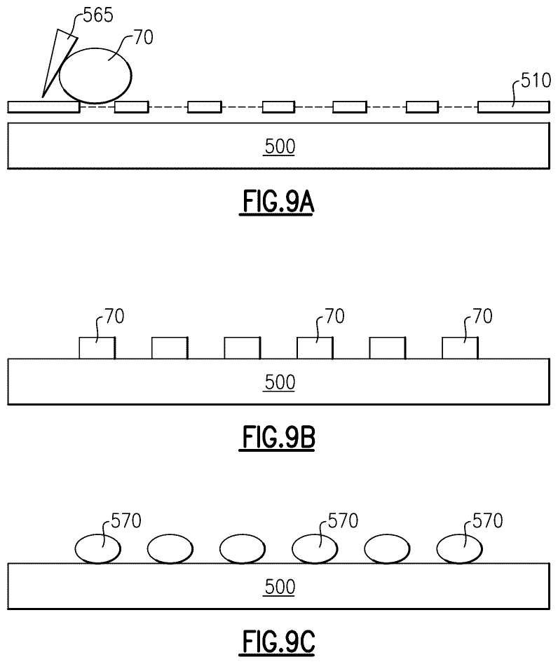

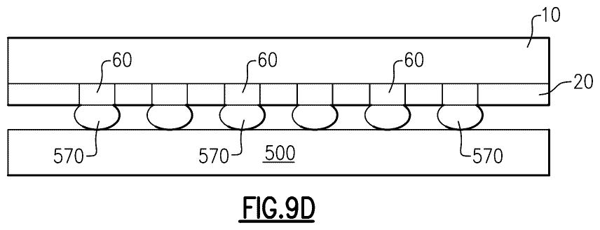

Various embodiments of the processes disclosed herein may be applicable not only to forming copper pillars on or in semiconductor wafers/die, but may also be useful in forming structures directly on a multichip module substrate, for example, a printed circuit board. In one example, contacts to which copper pillars of die as disclosed herein may be bonded may be formed on a multichip module substrate by stencil printing. As shown in FIG. 9A, a stencil 510 may be placed over a multichip module substrate 500 and a squeegee 565 may be used to deposit solder paste 70 through the stencil 510 onto the surface of the multichip module substrate 500 to form a desired pattern of solder contacts and/or conductive traces (FIG. 9B). The deposited solder paste 70 may then be reflowed to form a reflowed solder pattern 570 (FIG. 9C), and a die including exposed copper pillars 60 as disclosed herein may be flip chip bonded to the multichip module substrate 500 via the reflowed solder pattern 570 (FIG. 9D).

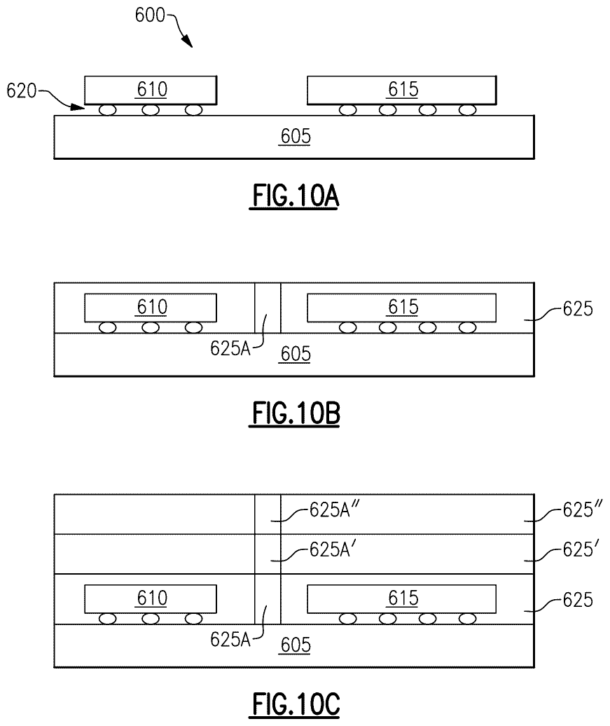

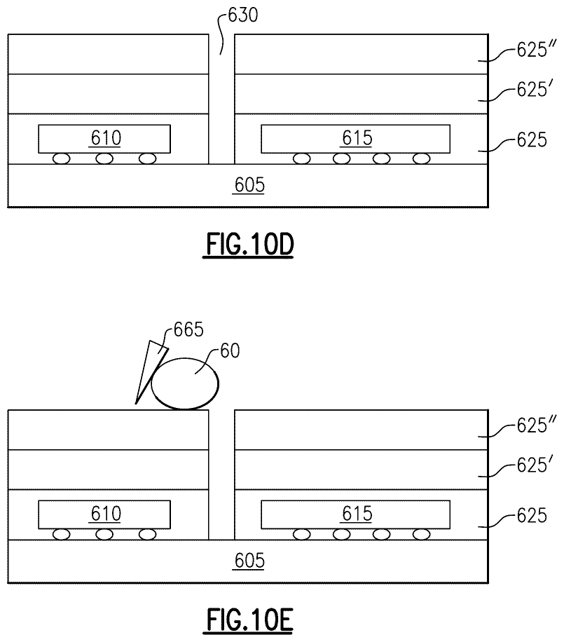

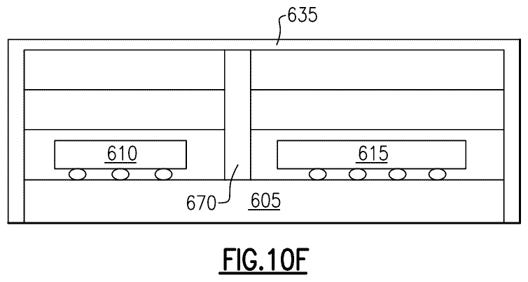

In further embodiments, copper paste may be used to form structures within multichip modules, for example, electromagnetic signal shielding or radio frequency signal shielding. As illustrated in FIG. 10A, a multichip module 600 may be provided with two or more devices 610, 615 mounted on a multichip module substrate 605, for example, a printed circuit board. Although only two devices 610, 615 are illustrated in FIG. 10A, the multichip module 600 may include more than two devices. The devices 610, 615 are illustrated as being flip-chip mounted with solder bonds 620, but may alternatively be mounted with wire bond connections. Either or both of the devices 610, 615 may be radio frequency devices, for example, filters, amplifiers, or any other form of device that may emit radio frequency signals that may possibly interfere with performance of the other device. It may thus be desirable to provide electromagnetic signal shielding, e.g., radio frequency signal shielding between the devices 610, 615 to at least partially shield each of the devices from radio frequency signals emitted by the other device. As shown in FIG. 10B, a layer of photodefinable dry film resist 625, for example, polyimide, may be deposited over and around the devices 610, 615 and a portion 625A of the photodefinable dry film resist 625 between the devices 610, 615 may be photolithographically exposed. Depending on the height of the devices 610, 615 or a desired height of a radio frequency signal shield to be defined between the devices 610, 615, one or more additional layers of photodefinable dry film resist 625′, 625″ may then be deposited over the layer of photodefinable dry film resist 625 and portions 625A′, 625A″ of the layers of photodefinable dry film resist 625′, 625″ over the photolithographically exposed portion 625A of the layer of photodefinable dry film resist 625 also photolithographically exposed. (FIG. 10C.) The layers of photodefinable dry film resist 625A, 625B, 625C may be developed to remove the photolithographically exposed portions 625A, 625A′, 625A″ and define a trench 630. (FIG. 10D.) The trench 630 may be defined between the devices 610, 615 as illustrated, or may partially or entirely circumscribe one or both of the devices 610, 615. Copper paste 60 may be deposited into the trench 630, for example, with a squeegee 665 under vacuum and may fully fill the trench 630. (FIG. 10E.) The copper paste 70 may be sintered to form a copper wall 670 between the devices 610, 615 that may provide electromagnetic signal shielding or radio frequency signal shielding of the devices 610, 615 from one another. (FIG. 10F.) If desired, an additional layer of a conductive material 635 may be deposited on the upper and/or side walls of the layer(s) of photodefinable dry film resist covering the devices 610, 615 to provide electromagnetic signal shielding or radio frequency signal shielding from sources external to the multichip module 600. The additional layer of conductive material 635 may be solder paste that is deposited and then sintered or another metal that is deposited by physical vapor deposition or by other methods known in the art.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of forming a copper pillar bump on a substrate, the method comprising:
depositing a layer of a first photoresist on the substrate;
exposing the first photoresist;
depositing a layer of a second photoresist on the layer of the first photoresist;
forming an aperture in the layer of the second photoresist by exposing and developing a portion of the layer of the second photoresist;
forming a cavity in the layer of the first photoresist below the aperture in the layer of the second photoresist;
depositing copper paste within the cavity; and
sintering the copper paste.

2. The method of claim 1 wherein the copper paste is deposited by screen printing.

3. The method of claim 2 wherein the copper paste is deposited by vacuum assisted screen printing.

4. The method of claim 1 further comprising exposing the layer of the first photoresist prior to depositing the layer of the second photoresist.

5. The method of claim 4 wherein forming the cavity in the layer of the first photoresist includes developing a portion of the layer of the first photoresist below the aperture in the layer of the second photoresist.

6. The method of claim 1 wherein the layer of the first photoresist and the layer of the second photoresist are not removed prior to sintering the copper paste.

7. The method of claim 1 wherein the aperture in the layer of the second photoresist is laterally offset from the cavity in the layer of the first photoresist.

8. The method of claim 1 further comprising depositing solder paste on top of the copper paste after sintering the copper paste, and reflowing the solder paste.

9. The method of claim 8 wherein the solder paste is deposited within the cavity.

10. The method of claim 8 further comprising removing the layer of the first photoresist and the layer of the second photoresist prior to reflowing the solder paste.

11. The method of claim 8 wherein the solder paste is deposited by screen printing.

12. The method of claim 11 wherein the solder paste is deposited by vacuum assisted screen printing.

13. The method of claim 8 wherein the solder paste is deposited at least partially within the aperture in the layer of the second photoresist.

14. The method of claim 8 further comprising removing an upper portion of the layer of the second photoresist prior to reflowing the solder paste with a lower portion of the layer of the second photoresist remaining while reflowing the solder paste.

15. The method of claim 1 further comprising forming a second copper pillar bump on the substrate.

16. The method of claim 15 wherein the aperture in the layer of the second photoresist defines a trench extending from the copper pillar bump to the second copper pillar bump.

17. The method of claim 16 further depositing the copper paste within the trench.

18. The method of claim 16 wherein the trench includes at least one spiral shaped portion.

19. The method of claim 15 wherein the aperture in the layer of the second photoresist defines a trench extending from the copper pillar bump.

20. The method of claim 19 further comprising forming a redistribution layer in the trench.

21. A method of forming a copper pillar bump on a substrate, the method comprising:
depositing a layer of a photoresist on the substrate;
depositing a release layer on an upper surface of the layer of the photoresist;
depositing a layer of epoxy on an upper surface of the release layer;
defining a cavity in the layer of epoxy, the release layer, and the layer of photoresist;
depositing copper paste within the cavity;
sintering the copper paste to form a sintered copper pillar;
peeling away the layer of epoxy and release layer from about the sintered copper pillar;
applying solder paste atop the sintered copper pillar; and
reflowing the solder paste.

22. The method of claim 21 wherein the release layer is polyvinyl alcohol.
